(19) United States
(12) Patent Application Publication
(10) Pub. No.: US 2025/0358997 A1
(43) Pub. Date: Nov. 20, 2025

(54) MEMORY DEVICE

(71) Applicant: Taiwan Semiconductor Manufacturing Company, Ltd., Hsinchu (TW)

(72) Inventor: Jhon-Jhy LIAW, Zhudong Township (TW)

(73) Assignee: Taiwan Semiconductor Manufacturing Company, Ltd., Hsinchu (TW)

(21) Appl. No.: 18/664,837

(22) Filed: May 15, 2024

(51) Int. Cl. H10B 10/00

(52) U.S. Cl. CPC H10B 10/125

(57) ABSTRACT

A memory device includes first and second SRAM cells shared a common boundary. The first SRAM cell includes first and second active regions, and first and second gate structures. The first gate structure and the first active region form a first pass-gate transistor. The second gate structure and the first and second active regions form a first pull-down transistor and a first pull-up transistor. The second SRAM cell includes third and fourth active regions, and third and fourth gate structures. The third gate structure and the third active region form a second pass-gate transistor. The fourth gate structure and the third and fourth active regions form a second pull-down transistor and a second pull-up transistor. The memory device includes a gate local connection structure over the first and third gate structures. The gate local connection structure electrically connects the first gate structure to the third gate structure.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs. Such scaling down has also increased the complexity of processing and manufacturing ICs and, for these advancements to be realized, similar developments in IC processing and manufacturing are needed.

As IC technologies progress towards smaller technology nodes, gate-all-around (GAA) transistors have been incorporated into memory devices (including, for example, static random-access memory (SRAM) cells) to reduce chip footprint while maintaining reasonable processing margins.

However, although existing memory device including GAA transistors have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a fragmentary diagrammatic top view of an integrated circuit (IC) chip 10, in portion or entirety, in accordance with some embodiments of the present disclosure.

FIGS. 2 and 3 are circuit diagrams of an SRAM circuit that can be implemented in an SRAM cell of an array in the memory region of FIG. 1, in accordance with some embodiments of the present disclosure.

FIG. 4 is a perspective view of a GAA transistor in an array of SRAM cells, in accordance with some embodiments of the present disclosure.

FIG. 5 is a cross-sectional view of a memory device for illustrating an interconnection structure, in accordance with some embodiments of the present disclosure

FIGS. 6A, 6B, 6C, and 6D are top views (or layouts) of two SRAM cells in a portion of an SRAM array that can be one embodiment of SRAM cells implemented in the memory region, in accordance with some embodiments of the present disclosure.

FIGS. 7A, 7B, 7C, and 7D are cross-sectional views of the SRAM array along lines A-A′, B-B′, C-C′, and D-D′ in FIGS. 6A to 6D, respectively, in accordance with some embodiments of the present disclosure.

FIGS. 8A and 8B are cross-sectional views of the SRAM array along lines B-B′ and C-C′ in FIGS. 6A to 6D, respectively, in accordance with some alternative embodiments of the present disclosure.

FIG. 9 is a top view (or layout) of three SRAM cells in a portion of an SRAM array that can be one embodiment of SRAM cells implemented in the memory region, in accordance with some embodiments of the present disclosure.

FIG. 10A is a top view (or layout) of two SRAM cells in a portion of an SRAM array that can be one embodiment of SRAM cells implemented in the memory region, in accordance with some alternative embodiments of the present disclosure.

FIG. 10B is a cross sectional view of the SRAM array along line E-E′ in FIG. 10A, in accordance with some alternative embodiments of the present disclosure.

FIG. 11 is a cross sectional view of the SRAM array along line E-E′ in FIG. 10A, in accordance with some alternative embodiments of the present disclosure.

FIG. 12 is a top view (or layout) of three SRAM cells in a portion of an SRAM array that can be one embodiment of SRAM cells implemented in the memory region, in accordance with some alternative embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to memory devices, and more particularly to an array of static random-access memory (SRAM) cells having field-effect transistors (FETs), such as three-dimensional gate-all-around (GAA) transistors, in an integrated circuit (IC) structure. Generally, a GAA transistor may include a plurality of vertically stacked nanostructures (e.g., nanosheets, nanowires, or nanorods) in a channel region of the transistor, thereby allowing better gate control, lowered leakage current, and improved scaling capability for various IC applications.

The gate-all-around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of the present disclosure offer advantages over the existing art, though it should be understood that other embodiments may offer different advantages, not all advantages are necessarily discussed herein, and no particular advantage is required for all embodiments. For example, embodiments discussed herein include a memory device with multiple SRAM cells, in which continuous gate end dielectric layers separate common gate structures shared by a pass-gate transistor of one SRAM cell and another pass-gate transistor of adjacent SRAM cell into two individual gate structures. The memory device further includes gate local connection structures disposed on the continuous gate end dielectric layers and electrically connecting the two individual gate structures of pass-gate transistors.

In this way, the continuous gate structure shared by two pass-gate transistors of two adjacent SRAM cells is divided into two individual gate structures, and the two pass-gate transistors are separated from each other by the continuous gate end dielectric layer. As a result, the source/drain (S/D) features of the two pass-gate transistors can be maximized since the existence of the continuous gate end dielectric layer prevents them from bridging together. Similarly, the active region widths (e.g., channel width) of the two pass-gate transistors can also be maximized since the continuous gate end dielectric layer separates the two pass-gate transistors. Moreover, the gate local connection structure connects the two individual gate structures, so that the gates of the two pass-gate transistors are still electrically connected to each other. In addition, since the continuous gate end dielectric layer also separates two pull-down transistors of the two adjacent SRAM cells, the S/D features and the active region widths of the two pull-down transistors can also be maximized. As a result, since the S/D features and the active region widths are maximized, the on-state current (Ion) and the S/D resistance of the pass-gate transistors and the pull-down transistors can be improved, thereby improving the performance of the SRAM cells.

The various aspects of the present disclosure will now be described in more detail with reference to the figures. For avoidance of doubts, the X-direction, the Y-direction, and the Z-direction in the figures are perpendicular to one another and are used consistently. Throughout the present disclosure, like reference numerals denote like features unless otherwise noted.

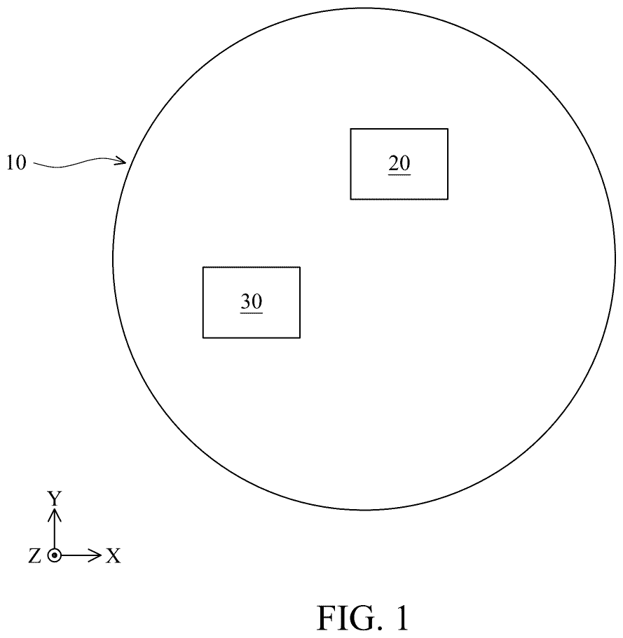

FIG. 1 is a fragmentary diagrammatic top view of an integrated circuit (IC) chip 10, in portion or entirety, in accordance with some embodiments of the present disclosure. IC chip 10 may include various passive microelectronic devices and active microelectronic devices, such as resistors, capacitors, inductors, diodes, p-type field effect transistors (PFETs), n-type field effect transistors (NFETs), metal-oxide semiconductor field effect transistors (MOSFETs), CMOS transistors, bipolar junction transistors (BJTs), laterally diffused MOS (LDMOS) transistors, high voltage transistors, high-frequency transistors, another suitable component, or a combination thereof. The various microelectronic devices can be configured to provide IC chip 10 with functionally distinct regions, such as a core region (also referred to as a logic region), a memory region (e.g., a static random access memory (SRAM) region), an analog region, a peripheral region (also referred to as an input/output (I/O) region), a dummy region, and/or other suitable region.

In some embodiments, IC chip 10 includes a memory region 20 and a logic region 30. Memory region 20 can include arrays of memory cells, each of which includes transistors and interconnection structures (also referred to as routing structures) that combine to provide a storage device and/or a storage function, such as a flip flop, a latch, another suitable memory device, or a combination thereof. In some embodiments, memory region 20 is configured with SRAM cells, dynamic random-access memory (DRAM) cells, non-volatile random-access memory (NVRAM) cells, flash memory cells, other suitable memory cells, or a combination thereof. Logic region 30 can include an array of standard cells, each of which includes transistors and interconnection structures that combine to provide a logic device and/or a logic function, such as an inverter, an AND gate, an NAND gate, an OR gate, an NOR gate, a NOT gate, an XOR gate, an XNOR gate, another suitable logic device, or a combination thereof. FIG. 1 has been simplified for the sake of clarity to better understand the inventive concepts of the present disclosure. Additional features can be added in IC chip 10, and some of the features described herein can be replaced, modified, or eliminated in other embodiments of IC chip 10.

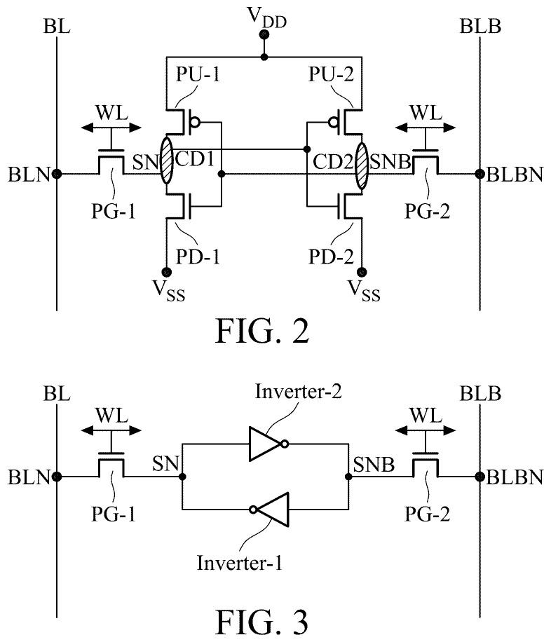

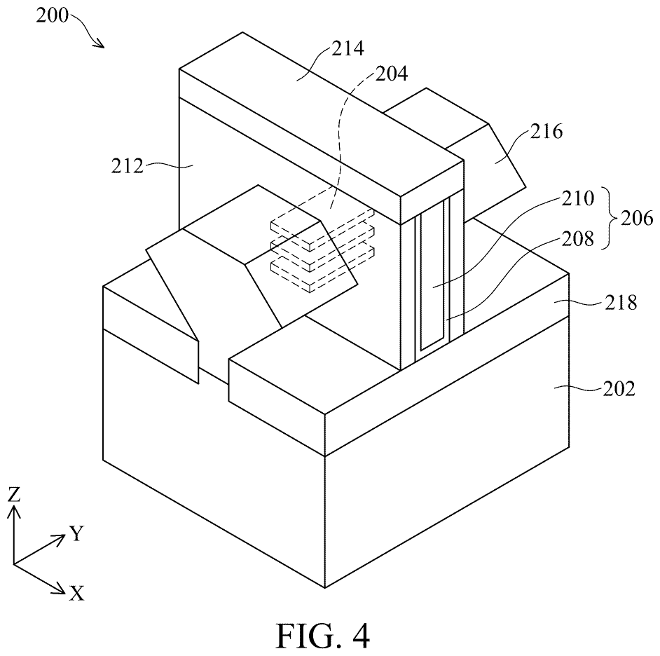

FIGS. 2 and 3 are circuit diagrams of an SRAM circuit that can be implemented in an SRAM cell (e.g., SRAM cells 500A, 500B, 500C, 500A′, 500B′, and 500C′ described below) of an array in the memory region 20 of FIG. 1, in accordance with some embodiments of the present disclosure. The circuit diagram of SRAM cell is merely exemplary, and in some embodiments, each of SRAM cells (e.g., SRAM cells 500A, 500B, 500C, 500A′, 500B′, and 500C′ described below) in the array is configured with an SRAM circuit similar to the SRAM cell shown in FIGS. 2 and 3.

For example, each of SRAM cells has a storage portion that includes a cross-coupled pair of inverters (also referred to as a latch), such as an Inverter-1 and an Inverter-2. Inverter-1 includes pull-up transistor PU-1 and pull-down transistor PD-1, and Inverter-2 includes pull-up transistor PU-2 and pull-down transistor PD-2. Pass-gate transistor PG-1 is connected to an output of Inverter-1 and an input of Inverter-2, and pass-gate transistor PG-2 is connected to an output of Inverter-2 and an input of Inverter-1. In operation, pass-gate transistor PG-1 and pass-gate transistor PG-2 provide access to the storage portion of their respective SRAM cell (i.e., Inverter-1 and Inverter-2) and can also be referred to as access transistors of their respective SRAM cell.

Each of SRAM cells (e.g., SRAM cells 500A, 500B, 500C, 500A′, 500B′, and 500C′ described below) is connected to and powered through a power supply voltage VDD (e.g., positive power supply voltage) and a reference voltage VSS (e.g., electrical ground). A gate of pull-up transistor PU-1 interposes a source, which is electrically coupled to the power supply voltage VDD, and a first common drain CD1 (i.e., a drain of pull-up transistor PU-1 and a drain of pull-down transistor PD-1). A gate of pull-down transistor PD-1 interposes a source, which is electrically coupled to the reference voltage VSS, and the first common drain CD1. A gate of pull-up transistor PU-2 interposes a source, which is electrically coupled to the power supply voltage VDD, and a second common drain CD2 (i.e., a drain of pull-up transistor PU-2 and a drain of pull-down transistor PD-2). A gate of pull-down transistor PD-2 interposes a source, which is electrically coupled to the reference voltage VSS, and the second common drain CD2. The first common drain CD1 provides a storage node SN that stores data in true form, and the second common drain CD2 provides a storage node SNB that stores data in complementary form, or vice versa, in some embodiments.

The gate of pull-up transistor PU1 and the gate of pull-down transistor PD-1 are coupled together and to the second common drain CD2, and the gate of pull-up transistor PU-2 and the gate of pull-down transistor PD-2 are coupled together and to the first common drain CD1. A gate of pass-gate transistor PG-1 interposes a drain connected to a bit-line node BLN, which is electrically coupled to a bit-line BL, and a source, which is electrically coupled to the first common drain CD1. A gate of pass-gate transistor PG-2 interposes a drain connected to a complementary bit-line node BLBN, which is electrically coupled to a complementary bit-line BLB (which may be referred to as a bit-line-bar BLB), and a source, which is electrically coupled to the second common drain CD2.

Gates of pass-gate transistors PG-1, PG-2 are connected to and controlled by a word-line WL, which allows selection of a respective SRAM cell, such as the SRAM cell 500A, for reading and/or writing. In some embodiments, the pass-gate transistors PG-1, PG-2 provide access to storage nodes SN, SNB, respectively, each of which can store a bit (e.g., a logical 0 or a logical 1), during read operations and/or write operations. For example, pass-gate transistors PG-1, PG-2 couple storage nodes SN, SNB, respectively, to bit-line BL and bit-line-bar BLB in response to voltage applied to gates of pass-gate transistors PG-1, PG-2 by word-line WL. In some embodiments, SRAM cells are single-port SRAMs. FIG. 2 and FIG. 3 have been simplified for the sake of clarity to better understand the inventive concepts of the present disclosure. Additional features can be added in the SRAM circuits of FIG. 2 and FIG. 3, and some of the features described herein can be replaced, modified, or eliminated in other embodiments of the SRAM circuits of FIG. 2 and FIG. 3.

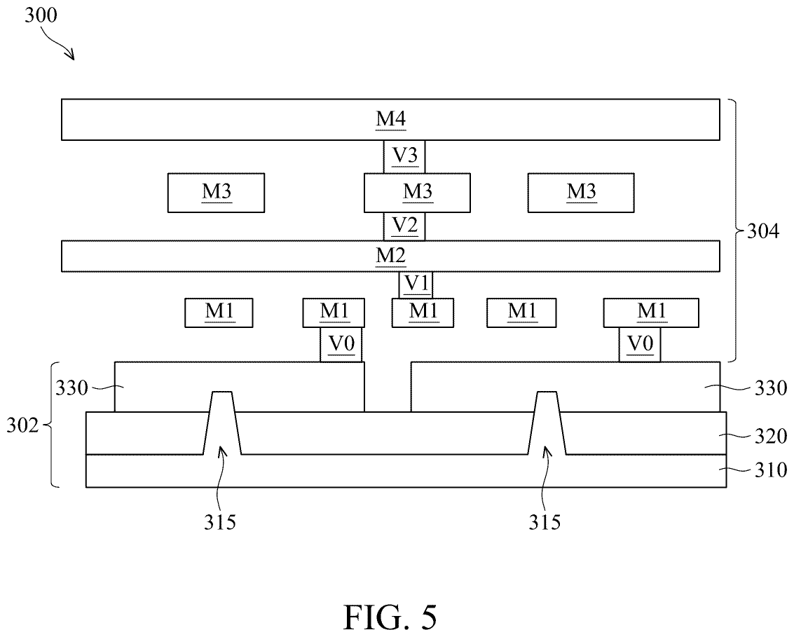

Each of the SRAM cells discussed above is constructed by transistors. The transistors may be planar transistors, fin field-effect transistor (FinFET) transistors, gate-all-around (GAA) transistors, or a combination thereof. For the sake of providing an example, an exemplary GAA transistor is illustrated in FIG. 4. However, it should be understood that the application should not be limited to a particular type of device, except as specifically claimed.

Referring to FIG. 4, a perspective view of an exemplary GAA transistor 200 is illustrated. The GAA transistor 200 is formed over a substrate 202. The substrate 202 may contains a semiconductor material, such as bulk silicon (Si). In some embodiments, after the resultant GAA transistor 200 is formed, the substrate 202 may be removed by a suitable process (e.g., a chemical mechanical polishing (CMP) process) for forming back-side interconnection.

The GAA transistor 200 also includes one or more nanostructures 204 (dash lines) extending in the Y-direction and stacked vertically (or arranged) in the Z-direction. More specifically, the nanostructures 204 are spaced apart from each other in the Z-direction. In some embodiments, the nanostructures 204 may also be referred to as channels, channel layers, nanosheets, or nanowires.

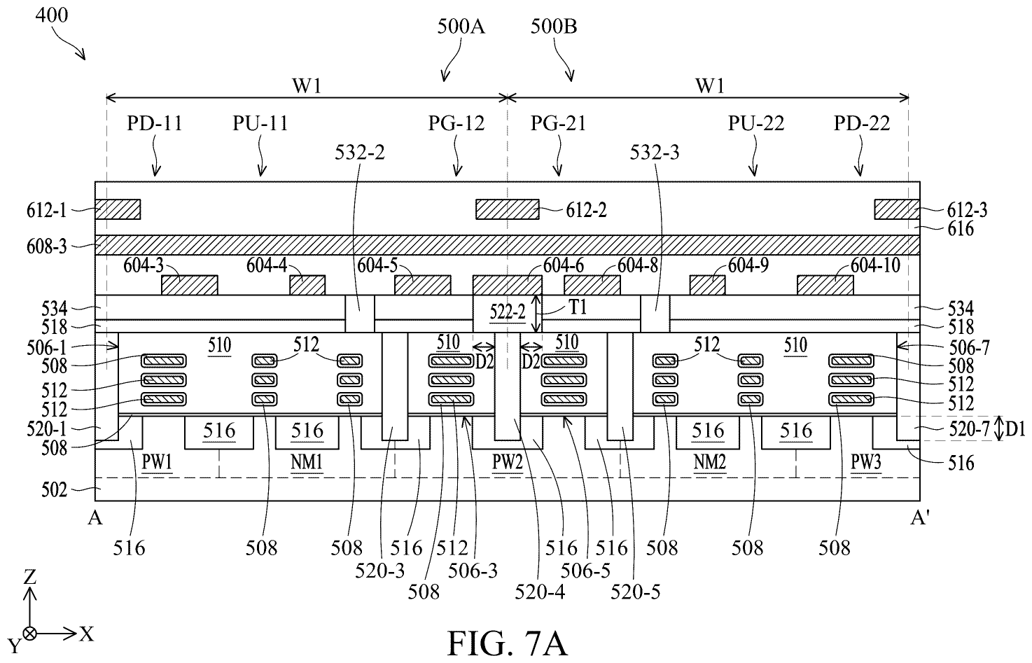

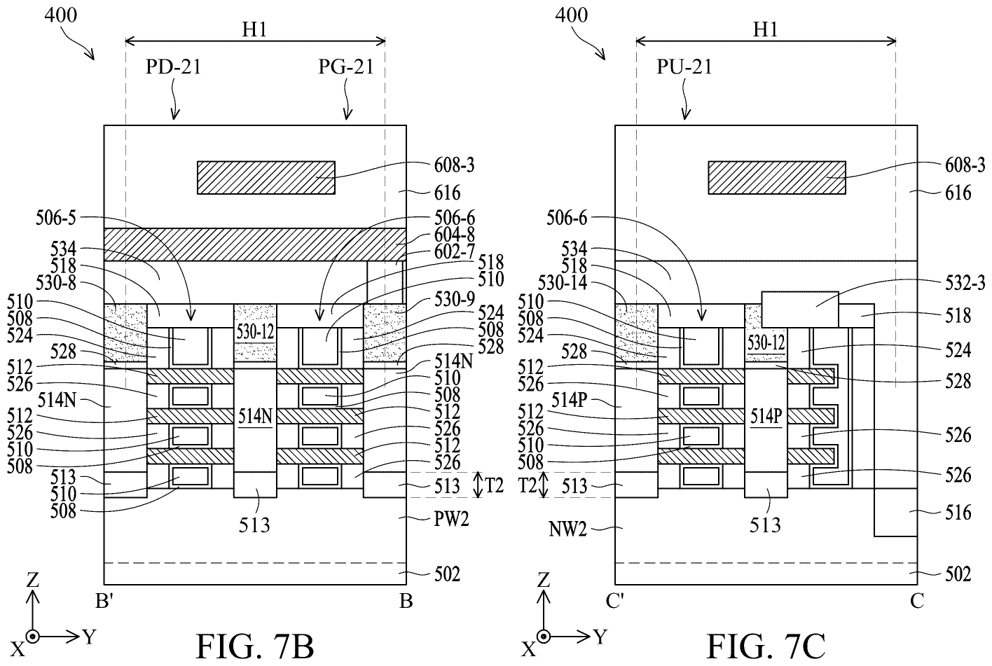

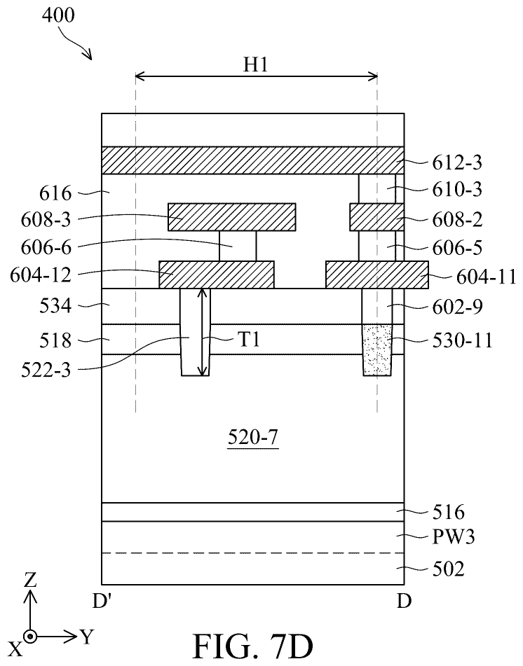

The GAA transistor 200 further includes a gate structure 206 including a gate dielectric layer 208 and a gate electrode 210. The gate dielectric layer 208 wraps around the nanostructures 204 and the gate electrode 210 wraps around the gate dielectric layer 208 (not shown in FIG. 4, may refer to FIGS. 7A to 7C). As shown in FIG. 4, gate spacers 212 are on sidewalls of the gate structure 206 and over the nanostructures 204 (not shown in FIG. 4, may refer to FIGS. 7B and 7C), in accordance with some embodiments. A gate top dielectric layer 214 is over the gate dielectric layer 208, the gate electrode 210, and the nanostructures 204. The gate top dielectric layer 214 is used for contact etch protection layer.

The GAA transistor 200 further includes source/drain features 216. As shown in FIG. 4, two source/drain features 216 are on opposite sides of the gate structure 206, in accordance with some embodiments. The nanostructures 204 (dash lines) extends in the Y-direction to connect one source/drain feature 216 to the other source/drain feature 216. The source/drain features 216 may also be referred to as source/drain, or source/drain regions. In some embodiments, source/drain feature(s) may refer to a source or a drain, individually or collectively dependent upon the context.

Isolation structure 218 is over the substrate 202 and under the gate dielectric layer 208, the gate electrode 210, and the gate spacers 212. The isolation structure 218 is used for isolating the GAA transistor 200 from other devices. In some embodiments, the isolation structure 218 may include different structures, such as shallow trench isolation (STI) structure, deep trench isolation (DTI) structure. Therefore, the isolation structure 218 is also referred as to as a STI feature or DTI feature.

FIG. 5 is a cross-sectional view of a memory device 300 for illustrating an interconnection structure, in accordance with some embodiments of the present disclosure. The memory device 300 may include a device region 302 and an interconnection structure 304. In some embodiments, the device region 302 includes a well region 310, fins 315, an isolation structure 320, and gate structures 330. In some embodiments, the well region 310 may be a p-type well region, and the material of the p-type well region includes Si with Boron (B) doping. In other embodiments, the well region 310 is an n-type well region, and the material of the n-type well region includes Si with Phosphorus (P) doping. The fins 315 (fins 315 may represent fin structures for FinFETs or stacks of nanostructures for GAA transistors) form the active regions over the well region 310, and the gate structures 330 are formed over the fins 315. Isolation structure 320 is over the well region 310 and under the gate structures 330.

In some embodiments, the interconnection structure 304 includes metal layer M1, metal layer M2 over the metal layer M1, metal layer M3 over the metal layer M2, and metal layer M4 over the metal layer M3, as shown in FIG. 5. Each of the metal layers M1, M2, M3, and M4 includes metal conductors. The interconnection structure 304 may further include vias V0, V1, V2, and V3 for connecting the metal conductor in the underlying metal layer to the metal conductor in the overlying metal layer. The vias and metal conductors electrically couple various transistors and/or components (e.g., gates, source/drain features, resistors, capacitors, and/or inductors), such that the various devices and/or components can operate as specified by the design requirements of circuit cells (e.g., logic cells and memory cells). It should be noted that, there may be more vias and metal conductors for connections.

In some embodiments, the vias V0 are connected to the gate structures (e.g., gate structures 330) of the transistors. Therefore, the vias V0 connected to the gate structures are also referred to as the gate vias. In some embodiments, the vias and metal conductors are used for the connections of the features of the transistor. In other embodiments, the vias and metal conductors are connected to voltage sources (the power supply voltage VDD or the reference voltage VSS discussed above) to provide voltage to the transistors. Therefore, the metal conductors connected to the voltage sources may be also referred to as the voltage metal conductors, the voltage lines, or voltage conductors.

For the operation speed of the SRAM cell, in the present disclosure, the metal conductors for interconnection need to have lower resistance. Therefore, the word-line conductors, bit-line conductors, and the bit-line-bar conductors are designed to be located in different metal layer for having larger width, thereby decreasing resistance. Therefore, in some embodiments, the metal conductors serving as VDD lines, bit-lines, and complementary bit-lines are designed to be located in the metal layer M1; the metal conductors serving as word-lines are designed to be located in the metal layer M2; and the metal conductors serving as VSS lines are designed to be located in the metal layer M3. In some embodiments, the memory device 300 further includes metal serving as second word-lines that are designed to be located in the metal layer M4. The second word-line is connected to the word-line in parallel to reduce resistance.

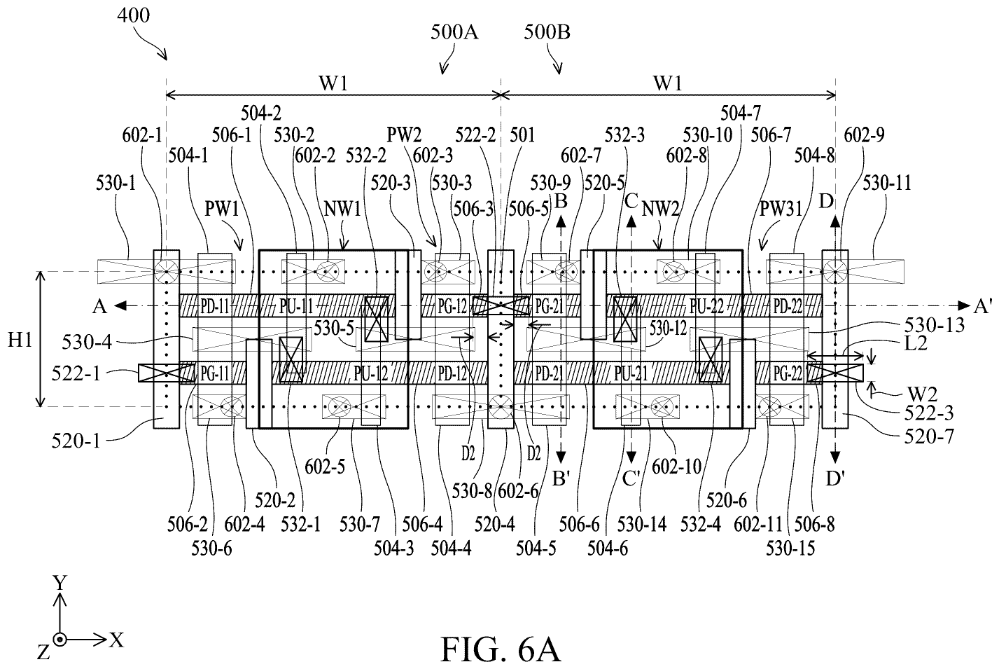

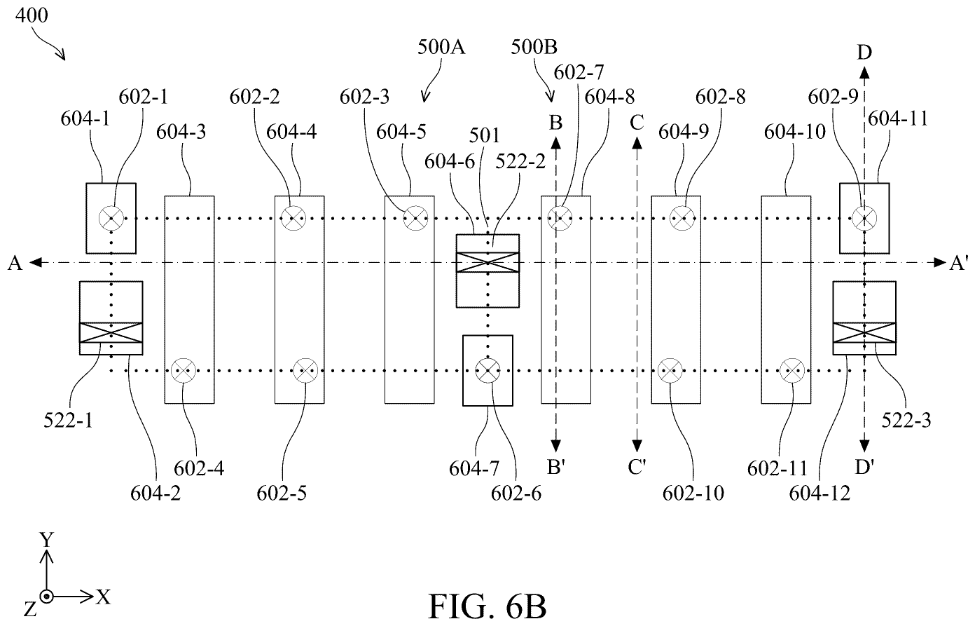

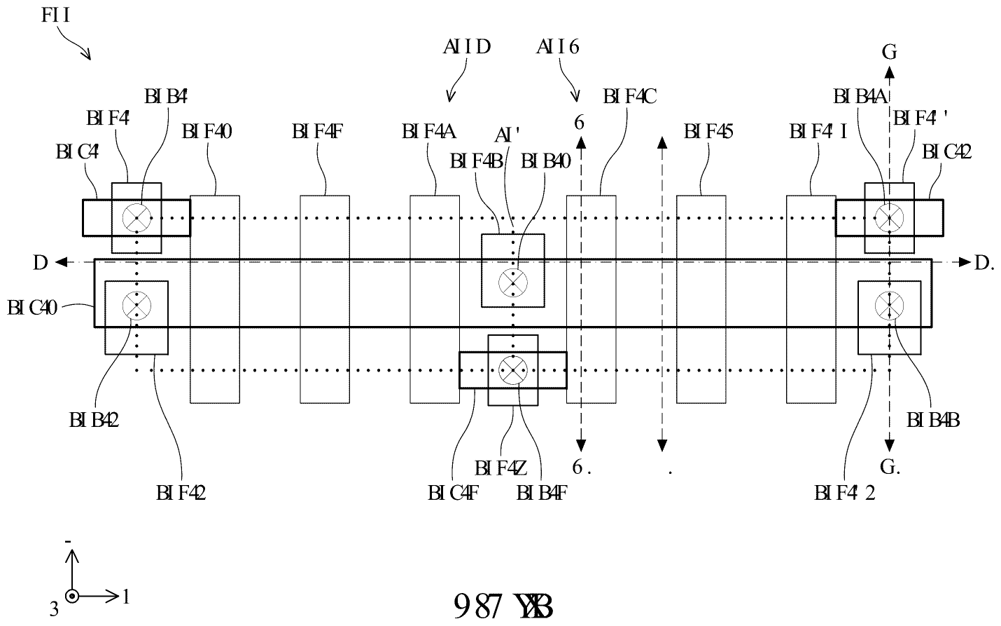

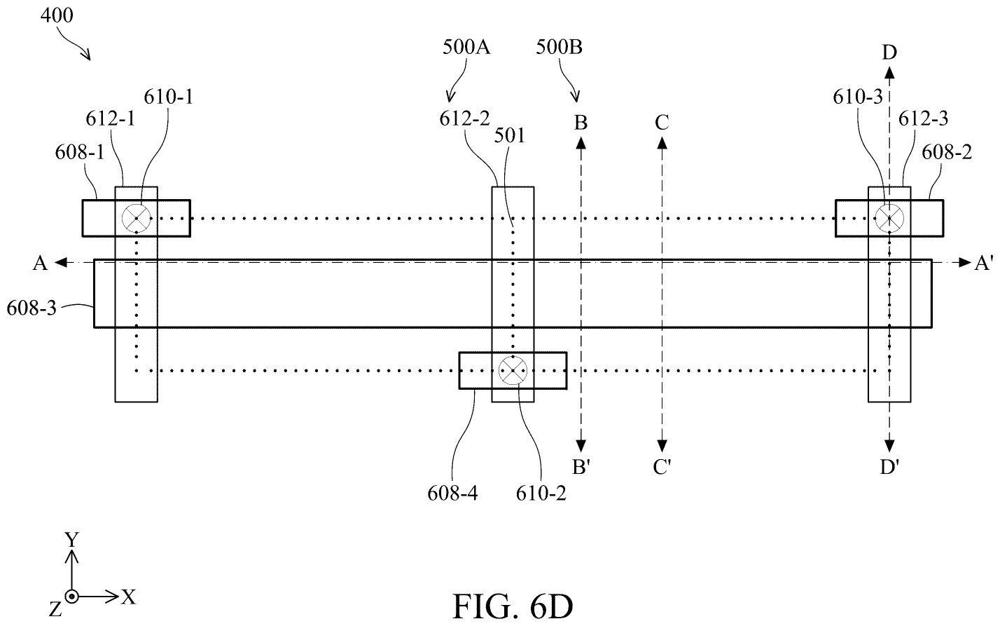

FIGS. 6A to 6D are top views (or layouts) of two SRAM cells 500A and 500B in a portion of an SRAM array 400 that can be one embodiment of SRAM cells implemented in the memory region 20, in accordance with some embodiments of the present disclosure. The SRAM cells 500A and 500B are adjacent to each other and share a common cell boundary 501 extending in the Y-direction. In some embodiments, the layout of SRAM cell 500B is a mirror image of the layout of SRAM cell 500A with respect to the common cell boundary 501.

FIG. 6A illustrates the features in the device region (including transistors) and vias vertically between the features and the first metal layer (M1). FIG. 6B illustrates the metal conductors in the first metal layer (M1) and vias vertically between the features and the first metal layer (M1). FIG. 6C illustrates the metal conductors in the first metal layer (M1) and the second metal layer (M2), and vias vertically between the first metal layer (M1) and the second metal layer (M2). FIG. 6D illustrates the metal conductors in the second metal layer (M2) and the third metal layer (M3), and vias vertically between the second metal layer (M2) and the third metal layer (M3).

FIG. 7A is a cross sectional view of the SRAM array 400 along line A-A′ in FIGS. 6A to 6D, in accordance with some embodiments of the present disclosure. FIG. 7B is a cross sectional view of the SRAM array 400 along line B-B′ in FIGS. 6A to 6D, in accordance with some embodiments of the present disclosure. FIG. 7C is a cross sectional view of the SRAM array 400 along line C-C′ in FIGS. 6A to 6D, in accordance with some embodiments of the present disclosure. FIG. 7D is a cross sectional view of the SRAM array 400 along line D-D′ in FIGS. 6A to 6D, in accordance with some embodiments of the present disclosure.

As shown in FIGS. 6A to 6D, the SRAM cells 500A and 500B are arranged adjacent to each other in the X-direction, and share the common cell boundary 501 that extends in the Y-direction, in accordance with some embodiments. In some embodiments, each of the SRAM cells 500A and 500B has cell boundaries indicated by the dotted rectangular box. Each of the SRAM cells 500A and 500B includes a cell width W1 that is corresponded to the cell boundaries extending in the X-direction, and a cell height H1 that is corresponded to the cell boundaries extending in the Y-direction (including the common cell boundary 501). In some embodiments, the cell height H1 spans over a total of 2 gate structures and is measured at about 2 gate pitches (also referred to as critical poly pitch (CPP)). Each gate pitch includes a gate length along the Y direction and a gate spacing between two adjacent gate structures along the Y direction. In some embodiments, the ratio of cell width W1 to cell height H1 is in a range from about 1.5 to about 3.

In some embodiments, the SRAM cell 500A includes active regions 504-1 to 504-4, and the SRAM cell 500B includes active region 504-5 to 504-8. In some embodiments, the active regions 504-1 to 504-8 (may be collectively referred to as the active regions 504) extend lengthwise in the Y-direction and are arranged (separated from each other) in the X-direction. Each of the active regions 504 includes channel regions, source regions, and drain regions (where source regions and drain regions are collectively referred to as source/drain regions herein) of transistors.

In some embodiments, the SRAM cell 500A further includes gate structures 506-1 to 506-4, and the SRAM cell 500B further includes gate structures 506-5 to 506-8. In some embodiments, the gate structures 506-1 to 506-8 (may be collectively referred to as the gate structures 506) extend lengthwise in the X-direction. The X-direction is perpendicular to the Y-direction. In some embodiments, the active regions 504-1 to 504-4 and the gate structures 506-1 to 506-4 are used for the SRAM cell 500A, and the active regions 504-5 to 504-8 and the gate structures 506-5 to 506-8 are used for the SRAM cell 500B.

In some embodiments, in the X-direction, the gate structure 506-1 is aligned with the gate structure 506-3, the gate structure 506-3 is aligned with the gate structure 506-5, and the gate structure 506-5 is aligned with the gate structure 506-7. Similarly, in the X-direction, the gate structure 506-2 is aligned with the gate structure 506-4, the gate structure 506-4 is aligned with the gate structure 506-6, and the gate structure 506-6 is aligned with the gate structure 506-8. In some embodiments, the gate structures 506-1 to 506-8 are disposed over the channel regions of the respective active regions 504-1 to 504-8 (i.e., (vertically stacked) nanostructures 512), and disposed between respective source/drain regions of the active regions 504-1 to 504-8 (i.e., source/drain features 514N and 514P). In some embodiments, the gate structures 506-1 to 506-8 wrap around the suspended and vertically stacked nanostructures 512 in the channel regions of the active regions 504-1 to 504-8 (as shown in FIGS. 7A to 7C).

In some embodiments, as shown in FIG. 6A, the gate structure 506-1 extends across and engages with the active regions 504-1 and 504-2 to form the pull-down transistor PD-11 and the pull-up transistor PU-11, respectively; the gate structure 506-2 extends across and engages with the active region 504-1 to form the pass-gate transistor PG-11; the gate structure 506-3 extends across and engages with the active region 504-4 to form the pass-gate transistor PG-12; and the gate structure 506-4 extends across and engages with the active regions 504-3 and 504-4 to form the pull-up transistor PU-12 and the pull-down transistor PD-12, respectively. The pass-gate transistors PG-11 and PG-12, the pull-down transistors PD-11 and PD-12, and the pull-up transistors PU-11 and PU-12 are included in the SRAM cell 500A.

In some embodiments, the pull-down transistor PD-11 and the pull-up transistor PU-11 share the gate structure 506-1 to construct an inverter as the Inverter-2 discussed above, and the pull-down transistor PD-12 and the pull-up transistor PU-12 share the gate structure 506-4 to construct an inverter as the Inverter-1 discussed above. Therefore, the SRAM cell 500A includes the inverter having the pull-down transistor PD-11 and the pull-up transistor PU-11, and the inverter having the pull-down transistor PD-12 and the pull-up transistor PU-12. The gate structure 506-1 and the gate structure 506-4 are also referred to as common gates or shared gate structures.

In some embodiments, as shown in FIG. 6A, the gate structure 506-5 extends across and engages with the active region 504-5 to form the pass-gate transistor PG-21; the gate structure 506-6 extends across and engages with the active regions 504-5 and 504-6 to form the pull-down transistor PD-21 and the pull-up transistor PU-21, respectively; the gate structure 506-7 extends across and engages with the active regions 504-7 and 504-8 to form the pull-up transistor PU-22 and the pull-down transistor PD-22, respectively; and the gate structure 506-8 extends across and engages with the active region 504-8 to form the pass-gate transistor PG-22. The pass-gate transistors PG-21 and PG-22, the pull-down transistors PD-21 and PD-22, and the pull-up transistors PU-21 and PU-22 are included in the SRAM cell 500B.

In some embodiments, the pull-down transistor PD-21 and the pull-up transistor PU-21 share the gate structure 506-6 to construct an inverter as the Inverter-1 discussed above, and the pull-down transistor PD-22 and the pull-up transistor PU-22 share the gate structure 506-7 to construct an inverter as the Inverter-2 discussed above. Therefore, the SRAM cell 500B includes the inverter having the pull-down transistor PD-21 and the pull-up transistor PU-21, and the inverter having the pull-down transistor PD-22 and the pull-up transistor PU-22. The gate structure 506-6 and the gate structure 506-7 are also referred to as common gates or shared gate structures.

Similar to the substrate 202 discussed above, referring to FIGS. 7A to 7D, the SRAM array 400 includes a substrate 502, over which the various features are formed, such as the gate structures 506 described above. The substrate 502 may contains a semiconductor material, such as bulk silicon (Si). In other embodiments, the substrate 502 may include other semiconductors, such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). Alternatively, the substrate 502 may be a semiconductor-on-insulator substrate, such as a silicon-on-insulator (SOI) substrate, a silicon germanium-on-insulator (SGOI) substrate, or a germanium-on-insulator (GOI) substrate. Semiconductor-on-insulator substrates may be fabricated using separation by implantation of oxygen (SIMOX), wafer bonding, and/or other suitable methods.

In some embodiments, the n-type wells NW1, NW2 and p-type wells PW1, PW2, PW3 are formed in or on the substrate 502, as shown in FIGS. 7A to 7D. The p-type wells PW1 to PW3 are p-type doped regions configured for n-type transistors (e.g., the pass-gate transistors PG-11, PG-12, PG-21, PG-22 and the pull-down transistors PD-11, PD-12, PD-21, PD-22). The n-type wells NW1 and NW2 are n-type doped regions configured for p-type transistors (e.g., the pull-up transistors PU-11, PU-12, PU-21, and PU-22). The n-type wells NW1 and NW2 are doped with n-type dopants, such as phosphorus, arsenic, other n-type dopant, or a combination thereof. The p-type wells PW1 to PW3 are doped with p-type dopants, such as boron, indium, other p-type dopant, or a combination thereof.

In some embodiments, the substrate 502 includes doped regions formed with a combination of p-type dopants and n-type dopants. The various n-type wells and/or p-type wells can be formed directly on and/or in the substrate 502, for example, providing a p-well structure, an n-well structure, a dual-well structure, a raised structure, or a combination thereof. An ion implantation process, a diffusion process, and/or other suitable doping process may be performed to form the various wells.

Similar to the isolation structure 218 discussed above, the SRAM array 400 may further include an isolation structure 516. The isolation structure 516 may include silicon oxide (SiO₂), silicon nitride (Si₃N₄), silicon oxynitride (SiON), other suitable isolation material (e.g., including silicon, oxygen, nitrogen, carbon, or other suitable isolation constituent), or combinations thereof. The isolation structure 516 may include different structures, such as STI structures, DTI structures, and/or local oxidation of silicon (LOCOS) structures. In some embodiments, the isolation structure 516 includes a multi-layer structure that fills the trenches, such as a silicon nitride comprising layer disposed over a thermal oxide comprising liner layer. In another example, the isolation structure 516 includes a dielectric layer disposed over a doped liner layer (including, for example, boron silicate glass (BSG) or phosphosilicate glass (PSG)). In yet another example, the isolation structure 516 include a bulk dielectric layer disposed over a liner dielectric layer, where the bulk dielectric layer and the liner dielectric layer include materials depending on design requirements.

In some embodiments, each of the transistors in the SRAM array 400 (e.g., the pass-gate transistors PG-11, PG-12, PG21 and PG-22, the pull-down transistors PD-11, PD-12, PD-21 and PD-22, and the pull-up transistors PU-11, PU-12, PU-21 and PU-22) includes nanostructures 512 similar to the nanostructures 204 discussed above. As shown in FIGS. 7A to 7C, the nanostructures 512 are suspended over the substrate 502, in accordance with some embodiments. In some embodiments, three nanostructures 310 are vertically stacked (or vertically arranged) from each other in the Z-direction for one transistor, as shown in FIGS. 7A to 7C. However, there may be another appropriate number of nanostructures in one transistor. For example, there may be from 2 to 10 nanostructures 512 in one transistor. The nanostructures 512 further extend lengthwise in the Y-direction (FIGS. 7B and 7C) and widthwise in the X-direction (FIG. 7A).

In some embodiments, the widths of the active regions 504 in the X-direction shown in FIG. 6A may represent widths of the nanostructures 512 in the X-direction. In some embodiments, the widths of the nanostructures 512 of the pass-gate transistors PG-11, PG-12, PG-21 and PG-22 and the pull-down transistors PD-11, PD-12, PD-21 and PD-22 are greater than the widths of the nanostructures 512 of the pull-up transistors PU-11, PU-12, PU-21 and PU-22. For example, as shown in FIGS. 6A and 7A, the widths of the nanostructures 512 in the channel regions of the active regions 504-1, 504-4, 504-5, and 504-8 in the X-direction is greater than the widths of the nanostructures 512 in the channel regions of the active regions 504-2, 504-3, 504-6, and 504-7 in the X-direction.

The nanostructures 512 may include a semiconductor material, such as Si, Ge, SiC, SiP, GaAs, GaP, InP, InAs, and/or InSb, SiGe, SiPC, GaAsP, AlInAs, AlGaAs, GaInAs, GaInP, and/or GaInAsP. In some embodiments, the nanostructures 512 for n-type transistors (e.g., the pass-gate and pull-down transistors) include Si, and the nanostructures 512 for p-type transistors (e.g., the pull-up transistors) include SiGe. In some embodiments, the nanostructures 512 are all made of silicon, and the type of the transistors depend on work function metal layer wrapping around the nanostructures 512. In some embodiments, the nanostructures 512 are epitaxially grown using an epitaxial growth process such as vapor-phase epitaxy (VPE), metal-organic CVD (MOCVD), molecular beam epitaxy (MBE), although other deposition processes, such as chemical vapor deposition (CVD), low pressure CVD (LPCVD), plasma-enhanced CVD (PECVD), atomic layer deposition (ALD), ultrahigh vacuum CVD (UHVCVD), remote plasma CVD (RPCVD), a combination thereof, or the like, may also be utilized.

In some embodiments, each of the gate structures 506-1 to 506-8 has a gate dielectric layer 508 and a gate electrode layer 510, as shown in FIGS. 7A to 7C. The gate dielectric layers 508 wrap around each of the nanostructures 512, and the gate electrode layers 510 wrap around the gate dielectric layers 508. In some embodiments, the gate structures 506 each further includes an interfacial layer (such as having silicon dioxide, silicon oxynitride, or other suitable materials) between the gate dielectric layer 508 and the nanostructures 512. In some embodiments, the gate dielectric layers 508 have a thickness in a range from about 0.5 nm (nanometer) to about 3 nm.

The gate dielectric layers 508 may include oxide with nitrogen doped dielectric material (initial layer) combined with metal content high-k dielectric material (k value (dielectric constant)>13). For example, the gate dielectric layers 508 may include hafnium oxide (HfO₂), which has a dielectric constant in a range from about 18 to about 40. Alternatively, the gate dielectric layers 508 may include other high-k dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr)TiO₃ (BST), Al₂O₃, Si₃N₄, oxynitrides (SiON), combinations thereof, or other suitable material. The gate dielectric layers 508 may be formed by chemical oxidation, thermal oxidation, CVD, physical vapor deposition (PVD), ALD, high-density plasma CVD (HDPCVD), MOCVD, RPCVD, PECVD, LPCVD, atmospheric pressure CVD (APCVD), flowable CVD (FCVD), and/or other suitable methods.

In some embodiments, the gate electrode layers 510 are formed to wrap around the gate dielectric layers 508 and the center portions of the nanostructures 512, as shown in FIGS. 7A to 7C. In some embodiments, the gate electrode layer 510 may include an n-type work function metal layer for n-type transistor (e.g., the pass-gate and pull-down transistors) or a p-type work function metal layer for p-type transistor (e.g., the pull-up transistors). In some embodiments, the n-type and p-type work function metal layers may include a material such as W, Al, Cu, TiN, Ti, TiAlN, TiAl, Pt, Ta, TaN, Co, Ni, TaC, TaCN, TaSiN, TaSi₂, NiSi₂, Mn, Zr, ZrSi₂, Ru, AlCu, Mo, MoSi₂, WN, other suitable work function materials, or combinations thereof. In some embodiments, the n-type and p-type work function metal layers may be deposited using a deposition process such as CVD, PVD, ALD, HDPCVD, MOCVD, RPCVD, PECVD, LPCVD, APCVD, FCVD, or the like, although any suitable deposition process may be used.

In some embodiments, the gate electrode layer 510 may include a single layer or alternatively a multi-layer structure. In some embodiments, the gate electrode layer 510 may further include a capping layer, a barrier layer, and a fill material (not shown). The capping layer may be formed adjacent to the gate dielectric layers 508 and may be formed from a metallic material such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The metallic material may be deposited using a deposition process such as CVD, PVD, ALD, HDPCVD, MOCVD, RPCVD, PECVD, LPCVD, APCVD, FCVD, or the like, although any suitable deposition process may be used.

The barrier layer may be formed adjacent the capping layer, and may be formed of a material different from the capping layer. For example, the barrier layer may be formed of a material such as one or more layers of a metallic material such as TiN, TaN, Ti, TiAlN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The barrier layer may be deposited using a deposition process such as CVD, PVD, ALD, HDPCVD, MOCVD, RPCVD, PECVD, LPCVD, APCVD, FCVD, or the like, although any suitable deposition process may be used.

In some embodiments, the SRAM array 400 further include gate top dielectric layers 518 that are over the gate dielectric layers 508, the gate electrode layers 510, and the nanostructures 512. The gate top dielectric layers 518 are similar to the gate top dielectric layer 214 discussed above. The gate top dielectric layers 518 are used for contact etch protection layer. The material of gate top dielectric layers 518 may be selected from a group consisting of oxide, SiOC, SiON, SiOCN, nitride base dielectric, metal oxide dielectric, Hf oxide (HfO₂), Ta oxide (Ta₂O₅), Ti oxide (TiO₂), Zr oxide (ZrO₂), Al oxide (Al₂O₃), Y oxide (Y₂O₃), combinations thereof, or other suitable materials.

In some embodiments, the SRAM array 400 includes gate end dielectric layers 520-1 to 520-7 (may be collectively referred to as the gate end dielectric layers 520) that extend in the Y-direction and are disposed at the ends of the gate structures 506, as shown in FIGS. 6A and 7A. The gate end dielectric layers 520 are used to physically separate the gate structures 506 aligned in the X-direction. For example, the gate end dielectric layer 520-1 is between and separates the gate structure 506-1 and a gate structure of a pull-down transistor in an adjacent SRAM cell (not shown), and is between and separates the gate structure 506-2 and a gate structure of a pass-gate transistor in the adjacent SRAM cell (not shown). For example, the gate end dielectric layer 520-2 is between and separates the gate structure 506-2 and 506-4, and the gate end dielectric layer 520-3 is between and separates the gate structure 506-1 and 506-3. For example, the gate end dielectric layer 520-4 is between the gate structures 506-3 and 506-5 and between the gate structures 506-4 and 506-4, and separates the gate structures 506-3 and 506-4 of the SRAM cell 500A from the gate structures 506-5 and 506-6 of the SRAM cell 500B. For example, the gate end dielectric layer 520-5 is between and separates the gate structure 506-5 and 506-7, and the gate end dielectric layer 520-6 is between and separates the gate structure 506-6 and 506-8. For example, the gate end dielectric layer 520-7 is between and separates the gate structure 506-7 and a gate structure of a pull-down transistor in an adjacent SRAM cell (not shown), and is between and separates the gate structure 506-8 and a gate structure of a pass-gate transistor in the adjacent SRAM cell (not shown).

In some embodiments, the gate end dielectric layer 520-1 extends along the cell boundary of the SRAM cell 500A that is opposite to the common cell boundary 501, and separates the SRAM cell 500A from an adjacent SRAM cell (not shown). In some embodiments, the gate end dielectric layer 520-4 extends along the common cell boundary 501 and between the SRAM cells 500A and 500B. In some embodiments, the gate end dielectric layer 520-7 extends along the cell boundary of the SRAM cell 500B that is opposite to the common cell boundary 501, and separates the SRAM cell 500B from an adjacent SRAM cell (not shown).

In some embodiments, the gate end dielectric layers 520-1, 520-4 and 520-7 extend in the Y-direction, and continuously extend across the whole cell height H1, as shown in FIG. 6A. That is, the dimensions of the gate end dielectric layers 520-1, 520-4 and 520-7 in the Y-direction are equal to or greater than the cell height H1. Therefore, the gate end dielectric layers 520-1, 520-4 and 520-7 may also be referred to as the continuous gate end dielectric layers.

In some embodiments, the gate end dielectric layer 520-2 extends in the Y-direction to separate the gate structures 506-2 and 506-4 without across the gate structure 506-1, and the gate end dielectric layer 520-3 extends in the Y-direction to separate the gate structures 506-1 and 506-3 without across the gate structure 506-4, as shown in FIG. 6A. In some embodiments, the gate end dielectric layer 520-5 extends in the Y-direction to separate the gate structures 506-5 and 506-7 without across the gate structure 506-6, and the gate end dielectric layer 520-6 extends in the Y-direction to separate the gate structures 506-6 and 506-8 without across the gate structure 506-7, as shown in FIG. 6A.

In some embodiments, the ends of the gate structure 506-1 are in contact with the gate end dielectric layers 520-1 and 520-3, and the ends of the gate structure 506-2 are in contact with the gate end dielectric layers 520-1 and 520-2. In some embodiments, the ends of the gate structure 506-3 are in contact with the gate end dielectric layers 520-3 and 520-4, and the ends of the gate structure 506-4 are in contact with the gate end dielectric layers 520-2 and 520-4. In some embodiments, the ends of the gate structure 506-5 are in contact with the gate end dielectric layers 520-4 and 520-5, and the ends of the gate structure 506-6 are in contact with the gate end dielectric layers 520-4 and 520-6. In some embodiments, the ends of the gate structure 506-7 are in contact with the gate end dielectric layers 520-5 and 520-7, and the ends of the gate structure 506-8 are in contact with the gate end dielectric layers 520-6 and 520-7.

In some embodiments, the gate end dielectric layers 520 extend into the isolation structure 516 by a distance D1, as shown in FIG. 7A. The distance D1 may be in a range from about 5 nm to about 60 nm. In some embodiments, the widths of the gate end dielectric layers 520 in the X-direction are in a range from about 5 nm to about 50 nm. In some embodiments, the gate end dielectric layers 520 may include Si₃N₄, SiO₂, SiC, SiON, SiOC, SiCN, SiOCN, carbon doped oxide, nitrogen doped oxide, carbon and nitrogen doped oxide, metal oxide dielectric, Hf oxide (HfO₂), Ta oxide (Ta₂O₅), Ti oxide (TiO₂), Zr oxide (ZrO₂), Al oxide (Al₂O₃), Y oxide (Y₂O₃), multiple metal content oxide, and a combination thereof. The gate end dielectric layers 520 may include a single layer or a multi-layer structure. The gate end dielectric layers 520 may be formed using a deposition process such as CVD, PVD, ALD, HDPCVD, MOCVD, RPCVD, PECVD, LPCVD, APCVD, FCVD, other suitable methods, or combinations thereof.

In some embodiments, the SRAM array 400 includes gate local connection structures 522-1 to 522-3 (may be collectively referred to as the gate local connection structures 522) that extend in the Y-direction, as shown in FIGS. 6A, 6B and 7A. The gate local connection structures 522 may be disposed on the gate end dielectric layers and on the gate structures of the two pass-gate transistors in the two adjacent SRAM cells. The gate local connection structure 522 may be used to connect the a gate structure of a pass-gate transistor in an SRAM cell to a gate structure of a pass-gate transistor in an adjacent SRAM cell.

For example, the gate local connection structure 522-2 is disposed on the gate structure 506-3 of the pass-gate transistor PG-12 in the SRAM cell 500A, the gate structure 506-5 of the pass-gate transistor PG-21 in the SRAM cell 500B, and the gate end dielectric layer 520-4, as shown in FIG. 7A. In some embodiments, the gate local connection structures 522-2 partially overlaps and is in contact with the gate structures 506-3 and 506-5, such that the gate structure 506-3 is electrically connected to the gate structures 506-5 through the gate local connection structures 522-2, as shown in FIGS. 6A and 7A. As a result, the gate structures 506-3 and 506-5 are physically separated by the gate end dielectric layer 520-4, while electrically connected together through the gate local connection structures 522-2 overlying the gate structures 506-3 and 506-5 and the gate end dielectric layer 520-4.

In this way, below the levels of the top surfaces of the gate structures 506-3, 506-5 and the source/drain features (e.g., the source/drain features 514N and 514P described below), the pass-gate transistor PG-12 in the SRAM cell 500A is physically separated from the pass-gate transistor PG-21 in the adjacent SRAM cell 500B by the gate end dielectric layer 520-4. Moreover, the gate structure 506-3 of the pass-gate transistor PG-12 in the SRAM cell 500A is electrically connected to the gate structure 506-5 of the pass-gate transistor PG-21 in the adjacent SRAM cell 500B by the gate local connection structure 522-2 above the top surfaces of the gate structures 506-3, 506-5 and the source/drain features. In comparison to the conventional SRAM cells where the adjacent pass-gate transistors of the adjacent SRAM cells share a common gate structure, the introduction of the continuous gate end dielectric layer (e.g., the gate end dielectric layers 520-1, 520-4 and 520-7) can physically separate the common gate structure into two individual gate structures (e.g., the gate structures 506-3 and 506-5) and physically separate the adjacent pass-gate transistors (e.g., the pass-gate transistors PG-12 and PG-21) form each other. As a result, the source/drain features of the adjacent pass-gate transistors (e.g., the pass-gate transistors PG-12 and PG-21) can be maximized since the continuous gate end dielectric layer prevents them from bridging together, and the active region widths (e.g., nanostructure width) of the adjacent pass-gate transistors can also be maximized since the continuous gate end dielectric layer separates the adjacent pass-gate transistors. Moreover, the introduction of the gate local connection structure (e.g., the gate local connection structure 522-2) can still electrically connect the gate structures (e.g., the gate structures 506-3 and 506-5) of the adjacent pass-gate transistors (e.g., the pass-gate transistors PG-12 and PG-21) in the adjacent SRAM cells together.

Similar to the gate local connection structures 522-2, the gate local connection structures 522-1 is disposed on the gate end dielectric layer 520-1, and disposed on and partially overlaps the gate structure 506-2 of the pass-gate transistor PG-11 in the SRAM cell 500A and the gate structure of a pass-gate transistor in an SRAM cell adjacent to the SRAM cell 500A (not shown). Therefore, the gate structure 506-2 is electrically connected to the gate structure of the pass-gate transistor in the SRAM cell adjacent to the SRAM cell 500A through the gate local connection structures 522-1. As a result, the gate structures 506-2 and the gate structure of the pass-gate transistor in the SRAM cell adjacent to the SRAM cell 500A are physically separated by the gate end dielectric layer 520-1, while electrically connected together through the gate local connection structures 522-1.

Similar to the gate local connection structures 522-2, the gate local connection structures 522-3 is disposed on the gate end dielectric layer 520-7, and disposed on and partially overlaps the gate structure 506-8 of the pass-gate transistor PG-22 in the SRAM cell 500B and the gate structure of a pass-gate transistor in an SRAM cell adjacent to the SRAM cell 500B (not shown). Therefore, the gate structure 506-8 is electrically connected to the gate structure of the pass-gate transistor in the SRAM cell adjacent to the SRAM cell 500B through the gate local connection structures 522-3. As a result, the gate structures 506-8 and the gate structure of the pass-gate transistor in the SRAM cell adjacent to the SRAM cell 500B are physically separated by the gate end dielectric layer 520-7, while electrically connected together through the gate local connection structures 522-3. As described above, the introduction of the continuous gate end dielectric layers and the gate local connection structures can allow the source/drain features and the active region widths of the pass-gate transistors to be maximized.

In some embodiments, the gate local connection structures 522-1 to 522-3 pass through the gate top dielectric layers 518 to contact the gate structures and the gate end dielectric layers. For example, the gate local connection structure 522-2 passes through the gate top dielectric layers 518 to contact the gate structures 506-3 and 506-5 and the gate end dielectric layer 520-4, as shown in FIG. 7A. In some embodiments, the bottom surfaces of the gate local connection structures 522-1 to 522-3 are coplanar with the top surfaces of the gate structures and the gate end dielectric layers. For example, the bottom surface of the gate local connection structure 522-2 is coplanar with the top surfaces of the gate structures 506-3 and 506-5 and the gate end dielectric layer 520-4, as shown in FIG. 7A.

In some embodiments, the gate local connection structures 522-1 to 522-3 may overlap with the gate structures (e.g., the gate structures 506-2, 506-3, 506-5, and 506-8) by a distance D2. For example, the gate local connection structure 522-2 overlaps with the gate structures 506-3 by the distance D2 and overlaps with the gate structures 506-5 by the distance D2, as shown in FIGS. 6A and 7A. In some embodiments, the distance D2 is in a range from about 3 nm to about 20 nm.

The gate local connection structures 522-1 to 522-3 may have a length L2 in the X-direction and a width W2 in the Y-direction, as shown in FIG. 6A. In some embodiments, a ration of the length L2 to the width W2 is greater than 3, such as in a range from about 3 to about 10. In some embodiments, the width W2 of the gate local connection structures 522-1 to 522-3 is smaller than the dimension of the gate structures 506 in the Y-direction. In other embodiments, the width W2 is equal to or greater than the dimension of the gate structures 506 in the Y-direction. In some embodiments, the gate local connection structures 522-1 to 522-3 have a thickness T1 in the Z-direction, and the thickness T1 is in a range from about 3 nm to about 30 nm, as shown in FIG. 7A.

In some embodiments, each of the gate local connection structures 522 may include a conductive material such as Al, Cu, W, Co, Ru, Mo, Ti, Ta, Ru, Rh, Ir, Pt, TiN, TiAl, TiAlN, TaN, TaC, combinations thereof, or the like. The gate local connection structures 522 may be formed by using a deposition process such as sputtering, CVD, PVD, ALD, HDPCVD, MOCVD, RPCVD, PECVD, LPCVD, APCVD, FCVD, electroplating, electroless plating, or the like. In some embodiments, the gate local connection structures 522 may include a single material structure or a multi-material structure.

In some embodiments, the SRAM cells 500A and 500B further include gate spacers 524 that are disposed on sidewalls of the gate structures 506 and over the nanostructures 512, as shown in FIGS. 7B and 7C. More specifically, the gate spacers 524 are over the nanostructures 512 and on top sidewalls of the gate structures 506, and thus are also referred to as gate top spacers or top spacers. The gate spacers 524 may include multiple dielectric materials and be selected from a group consisting of Si₃N₄, SiO₂, SiC, SiOC, SiON, SiOCN, carbon doped oxide, nitrogen doped oxide, porous oxide, air gap, or a combination thereof. In some embodiments, the gate spacers 524 may include a single layer or a multi-layer structure.

In some embodiments, the SRAM cells 500A and 500B further include inner spacers 526 that are disposed on sidewalls of the gate structures 506 and below the topmost nanostructures 512, as shown in FIGS. 7B and 7C. Furthermore, the inner spacers 526 are laterally between the source/drain features (e.g., source/drain features 514N or 514P described below) and the gate structures 506. The inner spacers 526 are also vertically between the adjacent nanostructures 512. The inner spacers 526 may include a dielectric material having higher k value than the gate spacers 524 and be selected from a group consisting of Si₃N₄, SiO₂, SiC, SiOC, SiON, SiOCN, air gap, or a combination thereof. In some embodiments, the thickness of the gate spacers 524 in the Y-direction and the thickness of the inner spacers 526 in the Y-direction are the same. In other embodiments, the thickness of the gate spacers 524 in the Y-direction is less than the thickness of the inner spacers 526 in the Y-direction since to the gate spacers 524 are trimmed during processes for forming source/drain contacts.

In some embodiments, the SRAM cells 500A and 500B further include bottom isolation layers 513 that are over the substrate 502, as shown in FIGS. 7B and 7C. More specifically, the bottom isolation layers 513 are vertically sandwiched between the source/drain features 514N/514P and the substrate 502. In some embodiments, the bottom isolation layers 513 are on the opposite sides of the gate structures 506 in the Y-direction, as shown in FIGS. 7B and 7C. In some embodiments, the bottom isolation layers 513 partially extend into the substrate 502, as shown in FIGS. 7B and 7C. In some embodiments, the bottom isolation layers 513 has a thickness T2 that is in a range from about 2 nm to about 25 nm.

The bottom isolation layers 513 may include dielectric materials and be selected from a group consisting of Si₃N₄, SiO₂, SiC, SiOC, SiON, SiOCN, carbon doped oxide, nitrogen doped oxide, porous oxide, air gap, or a combination thereof. In some embodiments, the bottom isolation layers 513 may include a single layer structure or alternatively a multi-layer structure. In some embodiments, the bottom isolation layers 513 may be formed by using a deposition process such as sputtering, CVD, PVD, ALD, HDPCVD, MOCVD, RPCVD, PECVD, LPCVD, APCVD, FCVD, electroplating, electroless plating, or the like.

In some embodiments, the SRAM cells 500A and 500B include source/drain features 514N and source/drain features 514P over the bottom isolation layers 513 and in the source/drain regions of the active regions 504, as shown in FIGS. 7B and 7C. More specifically, the source/drain features 514N are disposed over the bottom isolation layers 513 and on opposite sides of the respective gate structure 506 and nanostructures 512, and connected by the nanostructures 512 to form n-type transistors (e.g., the pass-gate transistors PG-11, PG-12, PG-21, PG-22, and the pull-down transistors PD-11, PD-12, PD-21, PD-22). Similarly, the source/drain features 514P are disposed over the bottom isolation layers 513 and on opposite sides of the respective gate structure 506 and nanostructures 512, and connected by the nanostructures 512 to form p-type transistors (e.g., the pull-up transistors PU-11, PU-12, PU-21, and PU-22).

In some embodiments, the bottom surfaces of the source/drain features 514N and 514P are in contact with the top surfaces of the bottom isolation layers 513, as shown in FIGS. 7B and 7C. In some embodiments, the source/drain features 514N and 514P are separated from the substrate 502 by the bottom isolation layers 513 in the Z-direction. In some embodiments, the top surfaces of the source/drain features 514N and 514P are substantially level with the topmost surfaces of the nanostructures 512. In other embodiments, the top surfaces of the source/drain features 514N and 514P are higher than the topmost surfaces of the nanostructures 512.

The source/drain features 514N and 514P may be formed by using epitaxial growth. In some embodiments, the source/drain features 514N may include epitaxially-grown material selected from a group consisting of SiP, SiC, SiPC, SiAs, Si, or a combination thereof. In some embodiments, the epitaxially-grown material of the source/drain features 514N may be doped with n-type dopants (such as phosphorus, arsenic, other n-type dopant, or combinations thereof) having a doping concentration in a range from about 2×10¹⁹/cm³ to 3×10²¹/cm³. In some embodiments, the source/drain features 514N for n-type transistors may be referred to as n-type source/drain features.

In some embodiments, the source/drain features 514P may include epitaxially-grown material selected from a group consisting of boron-doped SiGe, boron-doped SiGeC, boron-doped Ge, boron-doped Si, boron and carbon doped SiGe, or a combination thereof. In some embodiments, the epitaxially-grown material of the source/drain features 514P may be doped with p-type dopants (such as boron, indium, other p-type dopant, or combinations thereof) having a doping concentration in a range from about 1×10¹⁹/cm³ to 6×10²⁰/cm³. In some embodiments, the source/drain features 514P for p-type transistors may be referred to as p-type source/drain features.

In some embodiments, the SRAM cells 500A and 500B further include silicide layers 528 over the source/drain features 514N and 514P, as shown in FIGS. 7B and 7C. The silicide layers 528 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds.

In some embodiments, the SRAM cells 500A and 500B include source/drain contacts 530-1 to 530-15 (may be collectively referred to as the source/drain contacts 530), as shown in FIGS. 6A, 7B and 7C. In some embodiments, the source/drain contacts 530 extend lengthwise in the X-direction, as shown in FIG. 6A. In some embodiments, the source/drain contacts 530 are self-aligned source/drain contacts. It means that the source/drain contacts 530 are formed by using the gate spacers 524 as mask. Therefore, the source/drain contacts 530 are in direct contact with the gate spacers 524, as shown in FIGS. 7B and 7C. In some embodiments, the gate spacers 524 are trimmed since the gate spacers 524 serve as the mask for forming the source/drain contacts 530. Therefore, the thickness of the gate spacers 524 in the Y-direction is less than the thickness of the inner spacers 526 in the Y-direction, as discussed above.

In some embodiments, each of the source/drain contacts 530 is over and electrically connected to the respective source/drain features 514N/514P, as shown in FIGS. 6A, 7B, and 7C. Specifically, the source/drain contact 530-1 is over and electrically connected to the source/drain feature 514N of the pull-down transistor PD-11 of the SRAM cell 500A and a source/drain feature of a pull-down transistor of the SRAM cell (not shown) adjacent to the SRAM cell 500A. The source/drain contact 530-2 is over and electrically connected to the source/drain feature 514P of the pull-up transistor PU-11. The source/drain contact 530-3 is over and electrically connected to the source/drain feature 514N of the pass-gate transistor PG-12. The source/drain contact 530-4 is over and electrically connected to the source/drain feature 514N of (or shared by) the pull-down transistor PD-11 and the pass-gate transistor PG-11 (also referred to as common source/drain or common drain) and the source/drain feature 514P of the pull-up transistor PU-11. The source/drain contact 530-5 is over and electrically connected to the source/drain feature 514P of the pull-up transistor PU-12 and the source/drain feature 514N of (or shared by) the pass-gate transistor PG-12 and the pull-down transistor PD-12 (also referred to as common source/drain or common drain). The source/drain contact 530-6 is over and electrically connected to the source/drain feature 514N of the pass-gate transistor PG-11. The source/drain contact 530-7 is over and electrically connected to the source/drain feature 514P of the pull-up transistor PU-12. The source/drain contact 530-8 is over and electrically connected to the source/drain feature 514N of the pull-down transistor PD-12 in the SRAM cell 500A and the source/drain feature 514N of the pull-down transistor PD-21 in the SRAM cell 500B.

The source/drain contact 530-9 is over and electrically connected to the source/drain feature 514N of the pass-gate transistor PG-21. The source/drain contact 530-10 is over and electrically connected to the source/drain feature 514P of the pull-up transistor PU-22. The source/drain contact 530-11 is over and electrically connected to the source/drain feature 514N of the pull-down transistor PD-22 in the SRAM cell 500B and a source/drain feature of a pull-down transistor in the SRAM cell adjacent to the SRAM cell 500B (not shown). The source/drain contact 530-12 is over and electrically connected to the source/drain feature 514N of (or shared by) the pass-gate transistor PG-21 and the pull-down transistor PD-21 (also referred to as common source/drain or common drain) and the source/drain feature 514P of the pull-up transistor PU-21. The source/drain contact 530-13 is over and electrically connected to the source/drain feature 514P of the pull-up transistor PU-22 and the source/drain feature 514N of (or shared by) the pull-down transistor PD-22 and the pass-gate transistor PG-22 (also referred to as common source/drain or common drain). The source/drain contact 530-14 is over and electrically connected to the source/drain feature 514P of the pull-up transistor PU-21. The source/drain contact 530-15 is over and electrically connected to the source/drain feature 514N of the pass-gate transistor PG-22.

In some embodiments, the source/drain contacts 530 may each include a conductive material such as Al, Cu, W, Co, Ti, Ta, Ru, Rh, Ir, Pt, TiN, TiAl, TiAlN, TaN, TaC, combinations thereof, or the like. The source/drain contacts 530 may be formed by using a deposition process such as sputtering, CVD, PVD, ALD, HDPCVD, MOCVD, RPCVD, PECVD, LPCVD, APCVD, FCVD, electroplating, electroless plating, or the like. In some embodiments, the source/drain contacts 530 may each include a single conductive material layer or multiple conductive layers.

In some embodiments, the SRAM cells 500A and 500B further include butted contacts 532-1 to 532-4. In some embodiments, as shown in FIGS. 6A and 7A, the butted contact 532-1 is over the source/drain contact 530-4 and the gate structure 506-4, and the butted contact 532-1 electrically connects the source/drain contact 530-4 to the gate structure 506-4. The butted contact 532-2 is over the source/drain contact 530-5 and the gate structure 506-1, and the butted contact 532-2 electrically connects the source/drain contact 530-5 to the gate structure 506-1. In some embodiments, as shown in FIGS. 6A, 7A, and 7C, the butted contact 532-3 is over the source/drain contact 530-12 and the gate structure 506-7, and the butted contact 532-3 electrically connects the source/drain contact 530-12 to the gate structure 506-7. The butted contact 532-4 is over the source/drain contact 530-13 and the gate structure 506-6, and the butted contact 532-4 electrically connects the source/drain contact 530-13 to the gate structure 506-6. For the SRAM cell 500A, the butted contacts 532-1 and the source/drain contact 530-4 may correspond to the storage node SNB shown in FIGS. 2 and 3, and the butted contacts 532-2 and the source/drain contact 530-5 may correspond to the storage node SN shown in FIGS. 2 and 3. For the SRAM cell 500B, the butted contacts 532-3 and the source/drain contact 530-12 may correspond to the storage node SN shown in FIGS. 2 and 3, and the butted contacts 532-4 and the source/drain contact 530-13 may correspond to the storage node SNB shown in FIGS. 2 and 3.

In some embodiments, the butted contacts 532-1 to 532-4 may each include a conductive material such as Al, Cu, W, Co, Ti, Ta, Ru, Rh, Ir, Pt, TiN, TiAl, TiAlN, TaN, TaC, combinations thereof, or the like. The butted contacts 532-1 to 532-4 may be formed by using a deposition process such as sputtering, CVD, PVD, ALD, HDPCVD, MOCVD, RPCVD, PECVD, LPCVD, APCVD, FCVD, electroplating, electroless plating, or the like. In some embodiments, the butted contacts 532-1 to 532-4 may each include a single conductive material layer or multiple conductive layers.

In some embodiments, the SRAM cells 500A and 500B further include a (front-side) interconnection structure including vias, and metal conductors. More specifically, the SRAM cells 500A and 500B include vias 602 (including vias 602-1 to 602-11), metal conductors 604 (including metal conductors 604-1 to 604-12), vias 606 (including vias 606-1 to 606-6), metal conductors 608 (including metal conductors 608-1 to 608-4), vias 610 (including vias 610-1 to 610-3), metal conductors 612 (including metal conductors 612-1 and 612-3), gate local connection structures 522 (may function as gate vias), and an inter-metal dielectric (IMD) layer 616, which are over (or at the front-side of) the transistors in the SRAM cell 500A and 500B (e.g., the pass-gate transistors PG-11, PG-12, PG-21 and PG-22, the pull-down transistors PD-11, PD-12, PD-21 and PD-22, and the pull-up transistors PU-11, PU-12, PU-21 and PU-22).

In some embodiments, the vias 602, the metal conductors 604, the vias 606, the metal conductors 608, the vias 610, the metal conductors 612, and the gate local connection structures 522 are over the transistors in the SRAM cells 500A and 500B (e.g., the pass-gate transistors PG-11, PG-12, PG-21 and PG-22, the pull-down transistors PD-11, PD-12, PD-21 and PD-22, and the pull-up transistors PU-11, PU-12, PU-21 and PU-22). In some embodiments, the vias 602 and the gate local connection structures 522 are formed in an inter-layer dielectric (ILD) layer 534. In some embodiments, the metal conductors 604, the vias 606, the metal conductors 608, the vias 610, and the metal conductors 612 are formed in the IMD layer 616.

In some embodiments, the metal conductors 604, 608, and 612 are respectively in the metal layers M1, M2, and M3 as discussed above. Thus, the metal conductors 608 are over the metal conductors 604, and the metal conductors 612 are over the metal conductors 608. In some embodiments, the metal conductors 604 and 612 extend lengthwise in the Y-direction, and the metal conductors 608 extend lengthwise in the X-direction.

In some embodiments, each of the vias 602 is vertically between and electrically connected to the respective source/drain contact 530 and the respective metal conductor 604, and each of the gate local connection structures 522 is vertically between and electrically connected to the respective gate structure 506 and the respective metal conductor 604. In some embodiments, each of the vias 606 is vertically between and electrically connected to the respective metal conductor 604 and the respective metal conductor 608. In some embodiments, each of the vias 610 is vertically between and electrically connected to the respective metal conductor 608 and the respective metal conductor 612. In some embodiments, the vias 602, 606, and 610 may have circular shape in the top view. In other embodiments, the vias 602, 606, and 610 may have a rectangular shape in the top view.

In some embodiments, in the top view, the vias 602, 606, and 610 overlap the cell boundary of the SRAM cells 500A or 500B, as shown in FIGS. 6A and 6B. In some embodiments, the vias 606-1, 606-4, and 606-5 are directly over and overlap the vias 602-1, 602-6, and 602-9, respectively; and the vias 610-1, 610-2, and 610-3 are directly over and overlap the vias 606-1, 606-4, and 606-5, respectively, as shown in FIGS. 6A to 6D. Furthermore, in the top view, the metal conductors 604-1, 604-2, 604-6, 604-7, 604-11, 604-12, 612-1, 612-2, and 612-3 lengthwise overlap the cell boundary of the SRAM cells 500A or 500B.

In some embodiments, the metal conductors 604-4 and 604-9 serve as the VDD lines that are electrically coupled to a voltage node or voltage source (not shown) (e.g., the power supply voltage VDD). The metal conductors 604-4 and 604-9 may be electrically connected to the source/drain features 514P of the pull-up transistors PU-11 and PU-12 in the SRAM cell 500A and the pull-up transistors PU-21 and PU-22 in the SRAM cell 500B, as shown in FIGS. 6A and 6B. The metal conductor 604-4 may be electrically connected to the source/drain features 514P of the pull-up transistor PU-11 through the via 602-2 and the source/drain contact 530-2, and is electrically connected to the source/drain features 514P of the pull-up transistor PU-12 through the via 602-5 and the source/drain contact 530-7. The metal conductor 604-9 may be electrically connected to the source/drain features 514P of the pull-up transistor PU-21 through the via 602-10 and the source/drain contact 530-14, and is electrically connected to the source/drain features 514P of the pull-up transistor PU-22 through the via 602-8 and the source/drain contact 530-10. In some embodiments, the metal conductors 604-4 and 604-9 may be referred to as the (front-side) VDD conductors or the (front-side) VDD lines.

In some embodiments, the metal conductors 604-5 and 604-8 respectively serve as the bit-lines that are electrically connected to the source/drain features 514N of the pass-gate transistor PG-12 in the SRAM cell 500A and the pass-gate transistor PG-21 in the SRAM cell 500B, as shown in FIGS. 6A to 6B. The metal conductor 604-5 may be electrically connected to the source/drain feature 514N of the pass-gate transistor PG-12 through the via 602-3 and the source/drain contact 530-3. The metal conductor 604-8 may be electrically connected to the source/drain feature 514N of the pass-gate transistor PG-21 through the via 602-7 and the source/drain contact 530-9. In some embodiments, the metal conductors 604-5 and 604-8 may be referred to as (front-side) bit-line conductors.

In some embodiments, the metal conductors 604-3 and 604-10 respectively serve as the bit-line-bars that are electrically connected to the source/drain features 514N of the pass-gate transistor PG-11 in the SRAM cell 500A and the pass-gate transistor PG-22 in the SRAM cell 500B, as shown in FIGS. 6A to 6B. The metal conductor 604-3 may be electrically connected to the source/drain feature 514N of the pass-gate transistor PG-11 through the via 602-4 and the source/drain contact 530-6. The metal conductor 604-10 may be electrically connected to the source/drain feature 514N of the pass-gate transistor PG-22 through the via 602-11 and the source/drain contact 530-15. In some embodiments, the metal conductors 604-3 and 604-10 may be referred to as (front-side) bit-line-bar conductors.

In some embodiments, the metal conductor 608-3 serves as the word-line that is electrically connected to the gate structures 506 of the pass-gate transistors PG-11 and PG-12 in the SRAM cell 500A and the pass-gate transistors PG-21 and PG-22 in the SRAM cell 500B, as shown in FIGS. 6A to 6C. The metal conductor 608-3 may be electrically connected to the gate structure 506-2 of the pass-gate transistor PG-11 through the via 606-2, the metal conductor 604-2, and the gate local connection structure 522-1. The gate local connection structure 522-1 is electrically connected to the gate structure 506-2 of the pass-gate transistor PG-11 in the SRAM cell 500A and a gate structure of a pass-gate transistor in an SRAM cell adjacent to the SRAM cell 500A (not shown), as described above. The metal conductor 608-3 may be electrically connected to the gate structure 506-3 of the pass-gate transistor PG-12 and the gate structure 506-5 of the pass-gate transistor PG-21 through the via 606-3, the metal conductor 604-6, and the gate local connection structure 522-2. The gate local connection structure 522-2 is electrically connected to the gate structure 506-3 of the pass-gate transistor PG-12 in the SRAM cell 500A and the gate structure 506-5 of the pass-gate transistor PG-21 in the SRAM cell 500B, as described above.

The metal conductor 608-3 may be electrically connected to the gate structure 506-8 of the pass-gate transistor PG-22 through the via 606-6, the metal conductor 604-12, and the gate local connection structure 522-3. The gate local connection structure 522-3 is electrically connected to the gate structure 506-8 of the pass-gate transistor PG-22 in the SRAM cell 500B and a gate structure of a pass-gate transistor in an SRAM cell adjacent to the SRAM cell 500B (not shown), as described above. In some embodiments, the metal conductor 410-2 may be referred to as (front-side) word-line conductor. In some embodiments, the metal conductors 604-2, 604-6, and 604-12 may be referred to as word-line landing pads.

In some embodiments, the metal conductors 612-1 to 612-3 serve as the VSS lines that are electrically coupled to a voltage node or voltage source (not shown) (e.g., the reference voltage VSS). The metal conductors 612-1 to 612-3 may be electrically connected to the source/drain features 514N of the pull-down transistors PD-11 and PD-12 in the SRAM cell 500A and the pull-down transistors PD-21 and PD-22 in the SRAM cell 500B, as shown in FIGS. 6A to 6D. The metal conductor 612-1 may be electrically connected to the source/drain features 514N of the pull-down transistor PD-11 through the via 610-1, the metal conductors 608-1, the via 606-1, the metal conductors 604-1, the via 602-1, and the source/drain contact 530-1. The metal conductor 612-2 may be electrically connected to the source/drain features 514N of the pull-down transistors PD-12 and PD-21 through the via 610-2, the metal conductors 608-4, the via 606-4, the metal conductors 604-7, the via 602-6, and the source/drain contact 530-8.

The metal conductor 612-3 may be electrically connected to the source/drain features 514N of the pull-down transistor PD-22 through the via 610-3, the metal conductors 608-2, the via 606-5, the metal conductors 604-11, the via 602-9, and the source/drain contact 530-11. In some embodiments, the metal conductors 612-1 to 612-3 may be referred to as (front-side) VSS conductors or (front-side) VSS lines. In some embodiments, the metal conductors 604-1, 604-7, 604-11, 608-1, 608-2, and 608-4 may be referred to as VSS line landing pads.

In some embodiments, the SRAM array 400 further includes an additional metal conductor serving as an additional word-line. In these embodiments, the metal conductor 608-3 may be referred to as the first word-line and the additional metal conductor may be referred to as the second word-line. In some embodiments, the second word-line is disposed in the metal layer M4 above the metal layer M3 or a higher metal layer above the metal layer M4. In these embodiments, the second word-line is connected to the first word-line in parallel through other vias and metal conductors disposed between the first and second word-lines. In this way, the resistance of the overall word-line can be reduced.

The ILD layer 534 and the IMD 616 each may include one or more dielectric layers including dielectric materials, such as tetraethylorthosilicate (TEOS) oxide, un-doped silicate glass, or doped silicon oxide such as borophosphosilicate glass (BPSG), fluoride-doped silica glass (FSG), PSG, BSG, a low-k dielectric material, other suitable dielectric material, or a combination thereof. The materials of the vias 602, the metal conductors 604, the vias 606, the metal conductors 608, the vias 610, and the metal conductors 612 are selected from a group consisting of Al, Cu, W, Co, Ti, Ta, Ru, Rh, Ir, Pt, TiN, TiAl, TiAlN, TaN, TaC, combinations thereof, or the like.

It should be noted that, although the cross-sectional views shown in FIGS. 7B to 7D are taken from the SRAM cell 500B, since the SRAM cell 500A is a mirror image of the SRAM cell 500B, the structures shown in FIGS. 7B to 7D may also be applied to the SRAM cell 500A.

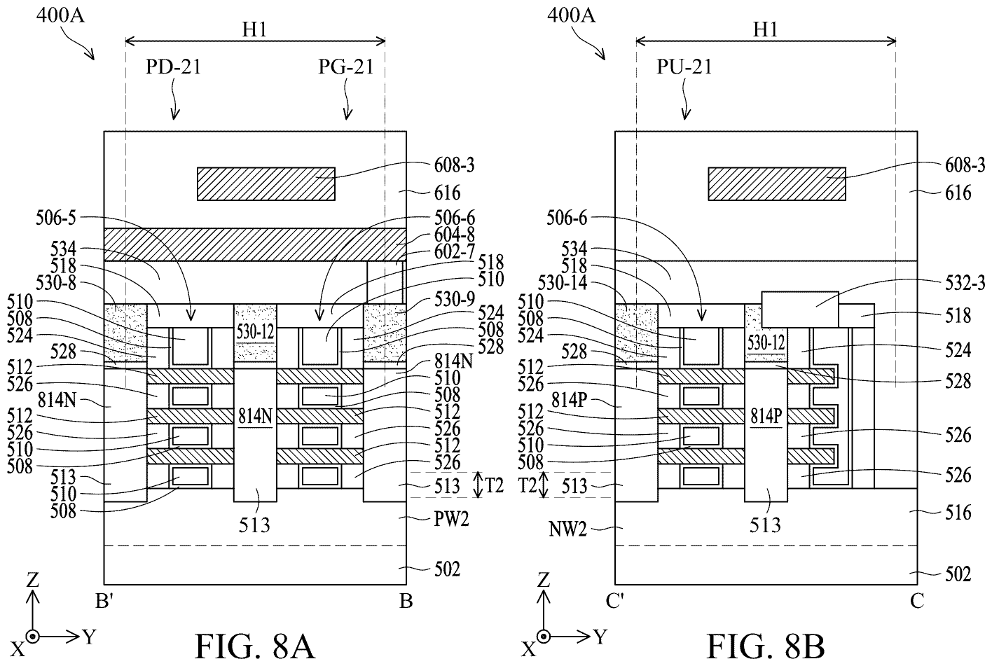

FIGS. 8A and 8B are Y-Z cross-sectional views of an alternative SRAM array (e.g., an SRAM array 400A) along the lines B-B′ and C-C′ in FIG. 6A, respectively, in accordance with some alternative embodiments of the present disclosure. The SRAM array 400A is similar to the SRAM array 400 discussed above, except that the bottom isolation layers 513 are omitted. In some embodiments, the source/drain features 514N of the pass-gate transistors PG-11, PG-12, PG-21, and PG-22 and the pull-down transistors PD-11, PD-12, PD-21, and PD-22 are replaced by the source/drain features 814N, and the source/drain features 814N extend into the substrate 502 since the bottom isolation layers 513 are omitted, as shown in FIG. 8A. In some embodiments, the source/drain features 514P of the pull-up transistors PU-11, PU-12, PU-21, and PU-22 are replaced by the source/drain features 814P, and the source/drain features 814P extend into the substrate 502 since the bottom isolation layers 513 are omitted, as shown in FIG. 8B.

In some embodiments, the source/drain features 814N and 814P each has a convex bottom surfaces. In some embodiments, the bottom surfaces of the source/drain features 814N and 814P are lower than the topmost surfaces of the substrate 502 and the bottommost surfaces of the gate structures 506. In some embodiments, the distance between the topmost surfaces of the substrate 502 and the bottom surfaces of the source/drain features 814N and/or 814P is in a range from about 5 nm to about 50 nm.

In other embodiments, the bottom isolation layers 513 are omitted from the source/drain regions of the pass-gate transistors and the pull-down transistors, but are reserved in the source/drain regions of the pull-down transistors. For example, the source/drain regions of the pass-gate transistors PG-11, PG-12, PG-21, and PG-22 and the pull-down transistors PD-11, PD-12, PD-21, and PD-22 are configured to include the source/drain features 814N, as shown in FIG. 8A, and the source/drain regions of the pull-up transistors PU-11, PU-12, PU-21, and PU-22 are configured to include the source/drain features 514P and the bottom isolation layers 513, as shown in FIG. 7C.

In certain embodiments, the bottom isolation layers 513 are omitted from the source/drain regions of the pull-up transistors, but are reserved in the source/drain regions of the pass-gate transistors and the pull-down transistors. For example, the source/drain regions of the pass-gate transistors PG-11, PG-12, PG-21, and PG-22 and the pull-down transistors PD-11, PD-12, PD-21, and PD-22 are configured to include the source/drain features 514N and the bottom isolation layers 513, as shown in FIG. 7B, and the source/drain regions of the pull-up transistors PU-11, PU-12, PU-21, and PU-22 are configured to include the source/drain features 814P, as shown in FIG. 8B.

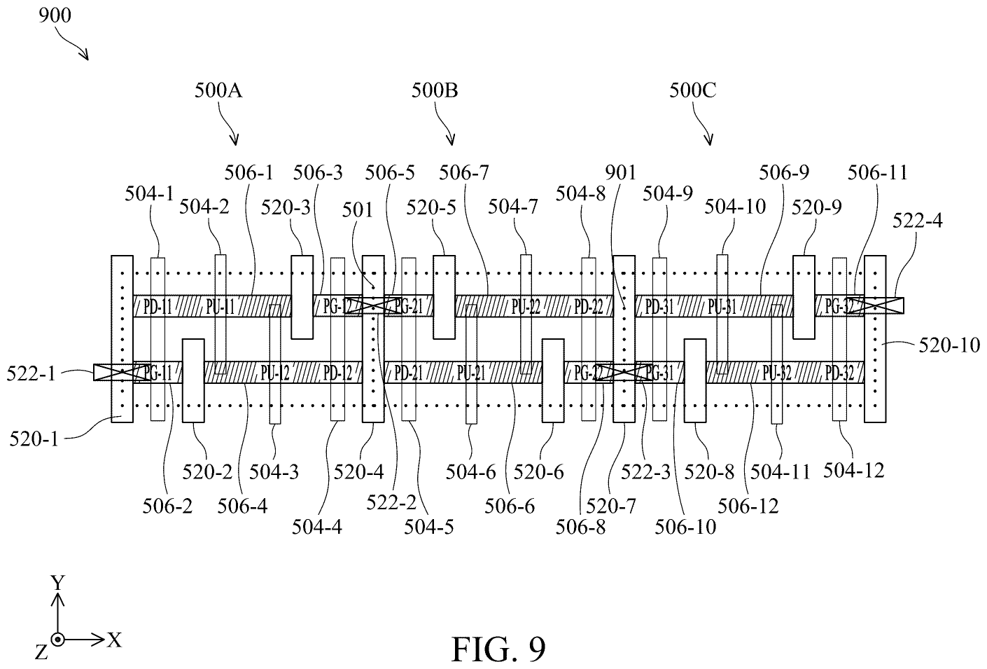

FIG. 9 is a top view (or layout) of three SRAM cells 500A, 500B, and 500C in a portion of an SRAM array 900 that can be one embodiment of SRAM cells implemented in the memory region 20, in accordance with some embodiments of the present disclosure. It should be noted that, for the purpose of simplicity and clarity, FIG. 9 only illustrates the active regions, the gate structures, the gate end dielectric layers, and the gate local connection structures. The components in the SRAM cells 500A and 500B are the same as those shown in FIGS. 6A to 6D. The SRAM cells 500B and 500C are adjacent to each other and share a common cell boundary 901 extending in the Y-direction. In some embodiments, the layout of SRAM cell 500C is a mirror image of the layout of SRAM cell 500B with respect to the common cell boundary 901. That is, the layout of the SRAM cell 500C is the same as or similar to the layout of the SRAM cell 500A.

In some embodiments, the SRAM cell 500C includes active regions 504-9 to 504-12 (may be collectively referred to as the active regions 504 with the active regions 504-1 to 504-8 described above) that extend lengthwise in the Y-direction and are arranged (separated from each other) in the X-direction. Each of the active regions 504-9 to 504-12 includes channel regions, source regions, and drain regions of transistors. In some embodiments, the SRAM cell 500C includes gate structures 506-9 to 506-12 (may be collectively referred to as the gate structures 506 with the active regions 506-1 to 506-8 described above) that extend lengthwise in the X-direction.

In some embodiments, in the X-direction, the gate structure 506-9 is aligned with the gate structure 506-7, and the gate structure 506-11 is aligned with the gate structure 506-9. Similarly, in the X-direction, the gate structure 506-10 is aligned with the gate structure 506-8, and the gate structure 506-12 is aligned with the gate structure 506-10. In some embodiments, the gate structures 506-9 to 506-12 are disposed over the channel regions of the respective active regions 504-9 to 504-12, and disposed between respective source/drain regions of the active regions 504-9 to 504-12. In some embodiments, the gate structures 506-9 to 506-12 wrap around the suspended and vertically stacked nanostructures in the channel regions of the active regions 504-9 to 504-12.

In some embodiments, in the top view, the gate structure 506-9 extends across and engages with the active regions 504-9 and 504-10 to form the pull-down transistor PD-31 and the pull-up transistor PU-31, respectively; the gate structure 506-10 extends across and engages with the active region 504-9 to form the pass-gate transistor PG-31; the gate structure 506-11 extends across and engages with the active region 504-12 to form the pass-gate transistor PG-32; and the gate structure 506-12 extends across and engages with the active regions 504-11 and 504-12 to form the pull-up transistor PU-32 and the pull-down transistor PD-32, respectively.

In some embodiments, the pull-down transistor PD-31 and the pull-up transistor PU-31 share the gate structure 506-9 to construct an inverter as the Inverter-2 discussed above, and the pull-down transistor PD-32 and the pull-up transistor PU-32 share the gate structure 506-12 to construct an inverter as the Inverter-1 discussed above. Therefore, the SRAM cell 500C includes the inverter having the pull-down transistor PD-31 and the pull-up transistor PU-31, and the inverter having the pull-down transistor PD-32 and the pull-up transistor PU-32. The gate structure 506-9 and the gate structure 506-12 are also referred to as common gates or shared gate structures.

In some embodiments, the SRAM cell 500C shares the gate end dielectric layer 520-7 with the SRAM cell 500B, and further includes gate end dielectric layers 520-8 to 520-10 (may be collectively referred to as the gate end dielectric layers 520 with the gate end dielectric layers 520-1 to 520-7 described above) that extend in the Y-direction. In some embodiments, the gate end dielectric layer 520-7 is between the gate structures 506-7 and 506-9 and between the gate structures 506-8 and 506-10, and separates the gate structures 506-7 and 506-8 of the SRAM cell 500B from the gate structures 506-9 and 506-10 of the SRAM cell 500C. In some embodiments, the gate end dielectric layer 520-8 is between and separates the gate structure 506-10 and 506-12, and the gate end dielectric layer 520-9 is between and separates the gate structure 506-9 and 506-11. In some embodiments, the gate end dielectric layer 520-10 is between and separates the gate structure 506-11 and a gate structure of a pass-gate transistor in the adjacent SRAM cell (not shown), and is between and separates the gate structure 506-12 and a gate structure of a pull-down transistor in the adjacent SRAM cell (not shown). In some embodiments, the gate end dielectric layer 520-7 extends along the common cell boundary 901 and between the SRAM cells 500B and 500C.

Similar to the gate end dielectric layers 520-1, 520-4 and 520-7, the gate end dielectric layer 520-10 may extend in the Y-direction and continuously extend across the whole cell height H1, as shown in FIG. 9. That is, the dimensions of the gate end dielectric layer 520-10 in the Y-direction are equal to or greater than the cell height H1. Therefore, the gate end dielectric layer 520-10 may also be referred to as the continuous gate end dielectric layer. In some embodiments, the gate end dielectric layer 520-8 extends in the Y-direction to separate the gate structures 506-10 and 506-12 without across the gate structure 506-9, and the gate end dielectric layer 520-9 extends in the Y-direction to separate the gate structures 506-9 and 506-11 without across the gate structure 506-12, as shown in FIG. 9.

In some embodiments, the SRAM cell 500C shares the gate local connection structure 522-3 with the SRAM cell 500B. The gate local connection structure 522-3 is disposed on the gate structure 506-8 of the pass-gate transistor PG-22 in the SRAM cell 500B, the gate structure 506-10 of the pass-gate transistor PG-31 in the SRAM cell 500C, and the gate end dielectric layer 520-7, as shown in FIG. 9. In some embodiments, the gate local connection structures 522-3 partially overlaps and is in contact with the gate structures 506-8 and 506-10, such that the gate structure 506-8 is electrically connected to the gate structures 506-10 through the gate local connection structures 522-3. As a result, the gate structures 506-8 and 506-10 are physically separated by the gate end dielectric layer 520-7, while electrically connected together through the gate local connection structures 522-3 overlying the gate structures 506-8 and 506-10 and the gate end dielectric layer 520-7.

In some embodiments, each of the gate structures of the pass-gate transistors in one SRAM cell are physically separated from the gate structure of the pass-gate transistor in the adjacent SRAM cell by the continuous gate end dielectric layer, while electrically connected to the gate structure of the pass-gate transistor in the adjacent SRAM cell through the gate local connection structure disposed over the continuous gate end dielectric layer. For example, the gate structure 506-5 of the pass-gate transistor PG-21 in the SRAM cell 500B is physically separated from the gate structure 506-3 of the pass-gate transistor PG-12 in the adjacent SRAM cell 500A by the gate end dielectric layer 520-4, while electrically connected to the gate structure 506-3 through the gate local connection structure 522-2 disposed over the gate end dielectric layer 520-4. Similarly, the gate structure 506-8 of the pass-gate transistor PG-22 in the SRAM cell 500B is physically separated from the gate structure 506-10 of the pass-gate transistor PG-31 in the adjacent SRAM cell 500C by the gate end dielectric layer 520-7, while electrically connected to the gate structure 506-10 through the gate local connection structure 522-3 disposed over the gate end dielectric layer 520-7. As described above, the introduction of the continuous gate end dielectric layers and the gate local connection structures can allow the source/drain features and the active region widths of the pass-gate transistors to be maximized.

In some embodiments, the SRAM cell 500C further include a gate local connection structure 522-4 (may be collectively referred to as the gate local connection structures 522 with the gate local connection structures 522-1 to 522-3 described above). Similar to the gate local connection structures 522-2, the gate local connection structures 522-4 is disposed on the gate end dielectric layer 520-10, and disposed on and partially overlaps the gate structure 506-11 of the pass-gate transistor PG-32 in the SRAM cell 500C and a gate structure of a pass-gate transistor in an SRAM cell adjacent to the SRAM cell 500C (not shown). Therefore, the gate structure 506-11 is electrically connected to the gate structure of the pass-gate transistor in the SRAM cell adjacent to the SRAM cell 500C through the gate local connection structures 522-4. As a result, the gate structures 506-11 and the gate structure of the pass-gate transistor in the SRAM cell adjacent to the SRAM cell 500C are physically separated by the gate end dielectric layer 520-10, while electrically connected together through the gate local connection structures 522-4.

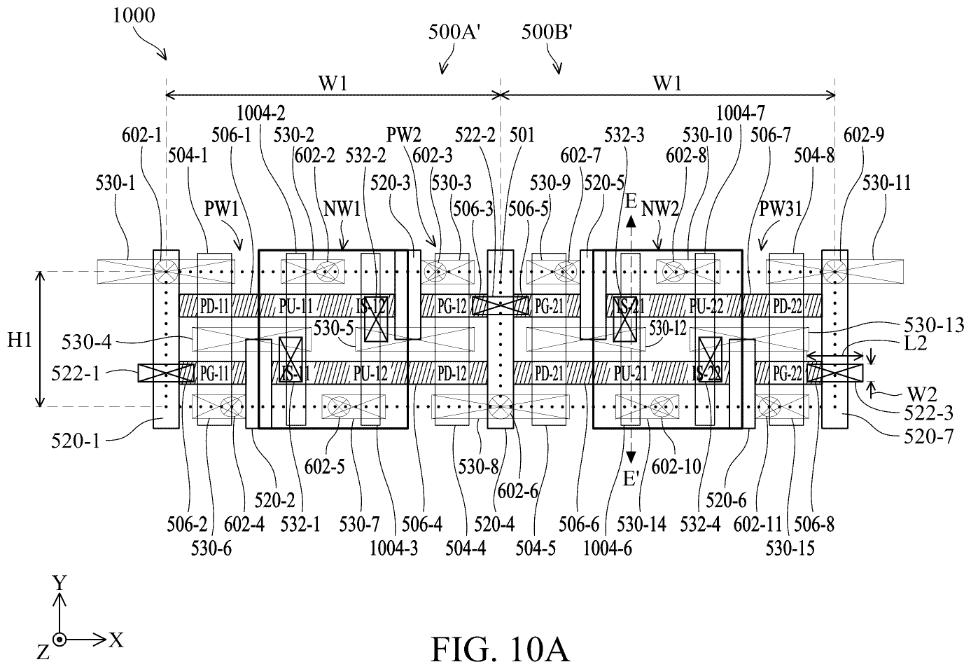

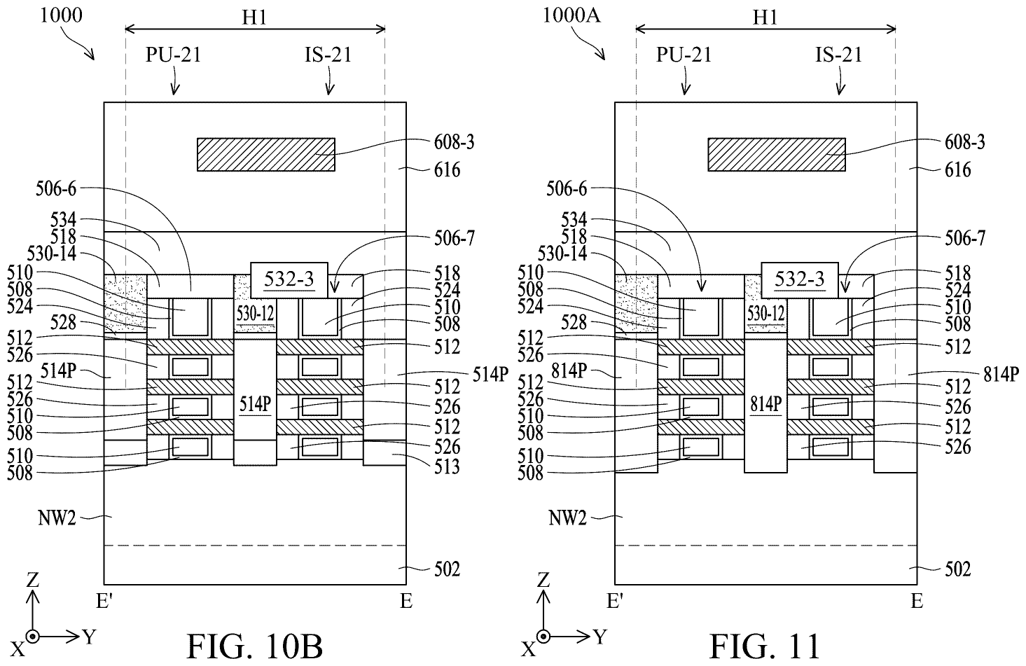

FIG. 10A is a top view (or layout) of two SRAM cells 500A′ and 500B′ in a portion of an SRAM array 1000 that can be one embodiment of SRAM cells implemented in the memory region 20, in accordance with some embodiments of the present disclosure. FIG. 10B is a cross sectional view of the SRAM array 1000 along line E-E′ in FIG. 10A, in accordance with some embodiments of the present disclosure. It should be noted that, for the purpose of simplicity and clarity, FIG. 10A illustrates the features in the device region (including transistors) and vias vertically between the features and the first metal layer (M1). The interconnection structure including metal layers (e.g., the second and third metal layers M2 and M3) above the first metal layer (M1) and the vias vertically between the metal layers are omitted from FIG. 10A, and are the same as or similar to those shown in FIGS. 6B to 6D. The SRAM cells 500A′ and 500B′ are similar to the SRAM cells 500A and 500B, except the active regions 504-2, 504-3, 504-6, and 504-7 shown in FIG. 6A are replaced by the active regions 1004-2, 1004-3, 1004-6, and 1004-7 shown in FIG. 10A. In some embodiments, the material and method used in forming the active regions 1004-2, 1004-3, 1004-6, and 1004-7 are the same as or similar to those of the active regions 504, and are not repeated herein.

In some embodiments, the active regions 1004-2, 1004-3, 1004-6, and 1004-7 extend in the Y-direction and across the whole cell height H1, as shown in FIG. 10A. In some embodiments, in the top view, the active region 1004-2 extends across and engages with the gate structures 506-1 and 506-4 to form the pull-up transistor PU-11 and the isolation transistor IS-11, respectively; the active region 1004-3 extends across and engages with the gate structures 506-1 and 506-4 to form the isolation transistor IS-12 and the pull-up transistor PU-12, respectively; the active region 1004-6 extends across and engages with the gate structures 506-7 and 506-6 to form the isolation transistor IS-21 and the pull-up transistor PU-21, respectively; and the active region 1004-7 extends across and engages with the gate structures 506-7 and 506-6 to form the pull-up transistor PU-22 and the isolation transistor IS-22, respectively. The isolation transistors IS-11 and IS-12 are included in the SRAM cell 500A′, and the isolation transistors IS-21 and IS-22 are included in the SRAM cell 500B′.

In some embodiments, each of the isolation transistors IS-11, IS-12, IS-21, and IS-22 has one source/drain feature that does not connect to the interconnection structure and is electrically floating. For example, the isolation transistor IS-21 has one source/drain feature 514P shared with the pull-up transistor PU-21 and the other source/drain feature 514P that is electrically floating, as shown in FIG. 10B. Since there is no source/drain contacts or other conductive features connected to the other source/drain feature 514P, the isolation transistor IS-21 is a non-functional transistor and will not affect the operation of the SRAM cell. Similarly, the isolation transistors IS-11, IS-12, and IS-22 are non-functional transistors and will not affect the operation of the SRAM cell.

Since the active regions 504-2, 504-3, 504-6, and 504-7 are replaced by the active regions 1004-2, 1004-3, 1004-6, and 1004-7, the active regions for the pull-up transistors are enlarged and have substantially the same length with other active regions (e.g., the active regions 504-1, 504-4, 504-5, and 504-8) in the Y-direction. In this way, the end control, the loading effect, and the pattern uniformity of the active regions can be improved, thereby improving the yield.

FIG. 11 is a Y-Z cross-sectional view of an alternative SRAM array (e.g., an SRAM array 1000A) along the line E-E′ in FIG. 10A, in accordance with some alternative embodiments of the present disclosure. In the embodiments shown in FIG. 10B, the source/drain regions of the pull-up transistors PU-11, PU-12, PU-21, and PU-22 and the isolation transistors IS-11, IS-12, IS-21, and IS-22 each includes the source/drain feature 514P and the bottom isolation layer 513. In the embodiments of the SRAM array 1000A, the bottom isolation layers 513 are omitted. In some embodiments, the source/drain features 514P of the pull-up transistors PU-11, PU-12, PU-21, and PU-22 and the isolation transistors IS-11, IS-12, IS-21, and IS-22 are replaced by the source/drain features 814P, and the source/drain features 814P extend into the substrate 502 since the bottom isolation layers 513 are omitted, as shown in FIG. 11. The configurations of the source/drain features 814P have been described above with reference to FIG. 8B, and are not repeated herein.

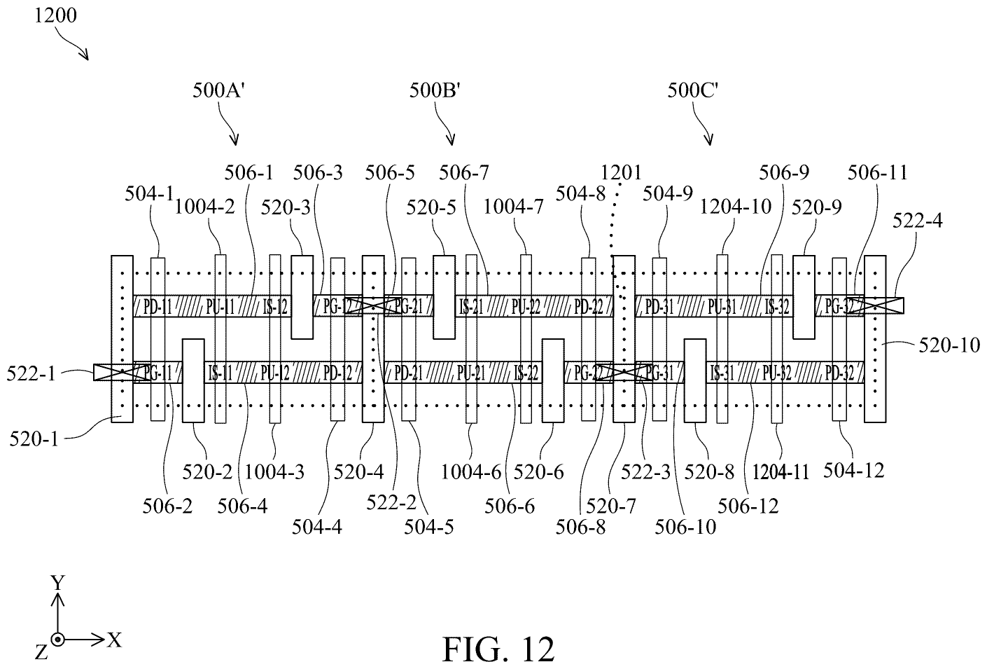

FIG. 12 is a top view (or layout) of three SRAM cells 500A′, 500B′, and 500C′ in a portion of an SRAM array 1200 that can be one embodiment of SRAM cells implemented in the memory region 20, in accordance with some embodiments of the present disclosure. It should be noted that, for the purpose of simplicity and clarity, FIG. 12 only illustrates the active regions, the gate structures, the gate end dielectric layers, and the gate local connection structures. The components in the SRAM cells 500A′ and 500B′ are the same as that shown in FIG. 10A. The SRAM cells 500B′ and 500C′ are adjacent to each other and share a common cell boundary 1201 extending in the Y-direction. In some embodiments, the layout of SRAM cell 500C′ is a mirror image of the layout of SRAM cell 500B′ with respect to the common cell boundary 1201. That is, the layout of the SRAM cell 500C′ is the same as or similar to the layout of the SRAM cell 500A′.

The SRAM cell 500C′ is similar to the SRAM cell 500C, except the active regions 504-10 and 504-11 shown in FIG. 9 are replaced by the active regions 1204-10 and 1204-11 shown in FIG. 12. In some embodiments, the material and method used in forming the active regions 1204-10 and 1204-11 are the same as or similar to those of the active regions 504, and are not repeated herein.

In some embodiments, the active regions 1204-10 and 1204-11 extend in the Y-direction and across the whole cell height H1, as shown in FIG. 12. In some embodiments, in the top view, the active region 1204-10 extends across and engages with the gate structures 506-9 and 506-12 to form the pull-up transistor PU-31 and the isolation transistor IS-31, respectively; and the active region 1204-11 extends across and engages with the gate structures 506-9 and 506-12 to form the isolation transistor IS-32 and the pull-up transistor PU-32, respectively. Similar to the isolation transistor IS-21, the isolation transistors IS-31 and IS-32 are non-functional transistors and will not affect the operation of the SRAM cell.

Since the active regions 504-10 and 504-11 are replaced by the active regions 1204-10 and 1204-11, the active regions for the pull-up transistors are enlarged and have substantially the same length with other active regions in the Y-direction. As described above, it can improve the end control, the loading effect, and the pattern uniformity of the active regions, and thus improve the yield.

The transistors of the SRAM cells discussed above each has a GAA structure or is a GAA transistor with nanostructures. In some embodiments, the transistors of the SRAM cells discussed above may be FinFETs with fin structures as channels. In these embodiments, the active regions of the SRAM cells with nanostructures in the channel regions are replaced with the active regions of the SRAM cells with fin structures in the channel regions. In further embodiments, the pass-gate transistors and the pull-down transistors in the SRAM array for high-speed applications are FinFETs with multiple fin structures; and the pull-up transistors in the SRAM array for high density usage are FinFETs with single fin structure.

The embodiments disclosed herein relate to memory device with multiple SRAM cells, in which continuous gate end dielectric layers and gate local connection structures are introduced. The continuous gate end dielectric layer physically separates the common gate structure shared by two pass-gate transistors in two adjacent SRAM cells into two individual gate structures, and the gate local connection structure disposed above the continuous gate end dielectric layers electrically connect the two individual gate structures. In this way, the source/drain features of the pass-gate transistors can be maximized since the continuous gate end dielectric layer prevents them from bridging together, and the active region widths (e.g., nanostructure width) of the pass-gate transistors can also be maximized since the continuous gate end dielectric layer separates the pass-gate transistors. At the same time, the two individual gate structures of two pass-gate transistors are still electrically connected together through the gate local connection structure. Furthermore, since the continuous gate end dielectric layer also separates two pull-down transistors of the two adjacent SRAM cells, the source/drain features and the active region widths of the pull-down transistors can also be maximized. As a result, since the source/drain features and the active region widths are maximized, the on-state current (Ion) and the source/drain resistance of the pass-gate transistors and the pull-down transistors can be improved, thereby improving the performance of the SRAM cells.

In one exemplary aspect, the present disclosure is directed to a memory device. The memory device includes a first static random access memory (SRAM) cell and a second SRAM cell that is adjacent to the first SRAM cell in the X-direction. The second SRAM cell shares a common boundary with the first SRAM cell. The first SRAM cell includes a first active region and a second active region extending in a Y-direction, and a first gate structure and a second gate structure extending in an X-direction that is perpendicular to the Y-direction. The first gate structure is engaged with the first active region to form a first pass-gate transistor. The second gate structure is engaged with the first active region and the second active region to form a first pull-down transistor and a first pull-up transistor, respectively. The second SRAM cell includes a third active region and a fourth active region extending in the Y-direction, and a third gate structure and a fourth gate structure extending in the X-direction. The third gate structure is engaged with the third active region to form a second pass-gate transistor. The fourth gate structure is engaged with the third active region and the fourth active region to form a second pull-down transistor and a second pull-up transistor, respectively. The memory device further includes a first gate end dielectric layer extending along the common boundary that extends in the Y-direction. The first gate end dielectric layer is between the first gate structure and the third gate structure, and separates the first gate structure from the third gate structure. The memory device further includes a first gate local connection structure extending in the X-direction and over the first gate structure, the third gate structure, and the first gate end dielectric layer. The first gate local connection structure electrically connects the first gate structure to the third gate structure.

In another exemplary aspect, the present disclosure is directed to a memory device. The memory device includes a first static random access memory (SRAM) cell and a second SRAM cell sharing a common boundary with the first SRAM cell. The common boundary extends in the Y-direction. The first SRAM cell includes a first pass-gate transistor, a first pull-down transistor, a first pull-up transistor, a second pass-gate transistor, a second pull-down transistor, and a second pull-up transistor. The first pass-gate transistor includes a first gate structure, and the first pull-down transistor and the first pull-up transistor share a second gate structure. The first gate structure and the second gate structure extend in the X-direction and are separated from each other in the Y-direction that is perpendicular to the X-direction. The second SRAM cell includes a third pass-gate transistor, a third pull-down transistor, a third pull-up transistor, a fourth pass-gate transistor, a fourth pull-down transistor, and a fourth pull-up transistor. The third pass-gate transistor includes a third gate structure, and the third pull-down transistor and the third pull-up transistor share a fourth gate structure. The third gate structure and the fourth gate structure extend in the X-direction, and are aligned with the first gate structure and the second gate structure along the X-direction, respectively. The third gate structure is separated from the first gate structure in the X-direction, and the fourth gate structure is separated from the second gate structure in the X-direction. The memory device further includes a first gate local connection structure disposed on the first gate structure and the third gate structure. The first gate local connection structure electrically connects the first gate structure to the third gate structure.

In yet another exemplary aspect, the present disclosure is directed to a memory device. The memory device includes a first static random access memory (SRAM) cell over a substrate and a second SRAM cell over the substrate and adjacent to the first SRAM cell. The first SRAM cell includes a first pass-gate transistor including first nanostructures that are vertically stacked and wrapped around by a first gate structure; a first pull-down transistor including second nanostructures that are vertically stacked and wrapped around by a second gate structure; and a first pull-up transistor including third nanostructures that are vertically stacked and wrapped around by the second gate structure. The first gate structure and the second gate structure extend in an X-direction and are separated from each other in a Y-direction that is perpendicular to the X-direction. The second SRAM cell includes a second pass-gate transistor including fourth nanostructures that are vertically stacked and wrapped around by a third gate structure; a second pull-down transistor including fifth nanostructures that are vertically stacked and wrapped around by a fourth gate structure; and a second pull-up transistor including sixth nanostructures that are vertically stacked and wrapped around by the fourth gate structure. The third gate structure and the fourth gate structure are aligned with the first gate structure and the second gate structure along the X-direction, respectively. The memory device further includes a first gate end dielectric layer disposed between the first SRAM cell and the second SRAM cell and extending the Y-direction. The first gate end dielectric layer physically separates the first gate structure from the third gate structure and physically separates the second gate structure from the fourth gate structure. The memory device further includes a first gate local connection structure disposed on the first gate structure, the third gate structure, and the first gate end dielectric layer. The first gate local connection structure electrically connects the first gate structure to the third gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a first static random access memory (SRAM) cell, wherein the first SRAM cell comprises:
a first active region and a second active region, extending in a Y-direction; and
a first gate structure and a second gate structure, extending in an X-direction that is perpendicular to the Y-direction, wherein the first gate structure is engaged with the first active region to form a first pass-gate transistor, and wherein the second gate structure is engaged with the first active region and the second active region to form a first pull-down transistor and a first pull-up transistor, respectively;
a second SRAM cell adjacent to the first SRAM cell in the X-direction, wherein the second SRAM cell shares a common boundary with the first SRAM cell, and the second SRAM cell comprises:
a third active region and a fourth active region, extending in the Y-direction; and
a third gate structure and a fourth gate structure, extending in the X-direction, wherein the third gate structure is engaged with the third active region to form a second pass-gate transistor, and wherein the fourth gate structure is engaged with the third active region and the fourth active region to form a second pull-down transistor and a second pull-up transistor, respectively;
a first gate end dielectric layer, extending along the common boundary that extends in the Y-direction, wherein the first gate end dielectric layer is between the first gate structure and the third gate structure, and separates the first gate structure from the third gate structure; and
a first gate local connection structure, extending in the X-direction and over the first gate structure, the third gate structure, and the first gate end dielectric layer, wherein the first gate local connection structure electrically connects the first gate structure to the third gate structure.

2. The memory device of claim 1,
wherein each of the first SRAM cell and the second SRAM cell has a cell width in the X-direction and a cell height in the Y-direction, and
wherein the first gate end dielectric layer continuously extends across the whole cell height.

3. The memory device of claim 2, wherein a ratio of the cell width to the cell height is in a range from 1.5 to 3.

4. The memory device of claim 1, wherein the first gate local connection structure partially overlaps each of the first gate structure and the third gate structure by a distance that is in a range from 3 nm to 20 nm.

5. The memory device of claim 1, wherein the first SRAM cell further comprises:
a fifth active region and a sixth active region, extending in the Y-direction;
a fifth gate structure extending in the X-direction, wherein the fifth gate structure is separated from the first gate structure in the X-direction and separated from the second gate structure in the Y-direction, and wherein the fifth gate structure is engaged with the fifth active region and the sixth active region to form a third pull-up transistor and a third pull-down transistor, respectively; and
a sixth gate structure extending in the X-direction, wherein the sixth gate structure is separated from the second gate structure in the X-direction and separated from the fifth gate structure in the Y-direction, and wherein the sixth gate structure is engaged with the sixth active region to form a third pass-gate transistor.

6. The memory device of claim 5, wherein the first SRAM cell further comprises:
a second gate end dielectric layer between the first gate structure and the fifth gate structure, wherein the second gate end dielectric layer separates the first gate structure from the fifth gate structure;
a third gate end dielectric layer between the second gate structure and the sixth gate structure, wherein the third gate end dielectric layer separates the second gate structure from the sixth gate structure; and
a fourth gate end dielectric layer, extending along a cell boundary that is opposite to the common boundary and extends in the Y-direction, wherein the fourth gate end dielectric layer is in contact with the fifth gate structure and the sixth gate structure.

7. The memory device of claim 6, wherein the first SRAM cell further comprising:
a second gate local connection structure, over the sixth gate structure and the fourth gate end dielectric layer, wherein the second gate local connection structure partially overlaps the sixth gate structure.

8. The memory device of claim 5,
wherein the first SRAM cell has a cell height in the Y-direction,
wherein the second active region and the fifth active region continuously extend across the whole cell height,
wherein the fifth gate structure is engaged with the second active region to form a first isolation transistor, and
wherein the second gate structure is engaged with the fifth active region to form a second isolation transistor.

9. The memory device of claim 1, wherein the first SRAM cell further comprises:
a word line landing pad, disposed on the first gate local connection structure;
a via, disposed on the word line landing pad; and
a word line, disposed on the via and extending in the X-direction, wherein the word line is electrically connected to the first gate structure and the third gate structure through the via, the word line landing pad, and the first gate local connection structure.

10. A memory device, comprising:
a first static random access memory (SRAM) cell, comprising:
a first pass-gate transistor, a first pull-down transistor, a first pull-up transistor, a second pass-gate transistor, a second pull-down transistor, and a second pull-up transistor,
wherein the first pass-gate transistor comprises a first gate structure and the first pull-down transistor and the first pull-up transistor share a second gate structure,
wherein the first gate structure and the second gate structure extend in an X-direction and are separated from each other in a Y-direction that is perpendicular to the X-direction,
a second SRAM cell sharing a common boundary with the first SRAM cell, wherein the common boundary extends in the Y-direction, wherein the second SRAM cell comprises:
a third pass-gate transistor, a third pull-down transistor, a third pull-up transistor, a fourth pass-gate transistor, a fourth pull-down transistor, and a fourth pull-up transistor,
wherein the third pass-gate transistor comprises a third gate structure and the third pull-down transistor and the third pull-up transistor share a fourth gate structure,
wherein the third gate structure and the fourth gate structure extend in the X-direction, and are aligned with the first gate structure and the second gate structure along the X-direction, respectively,
wherein the third gate structure is separated from the first gate structure in the X-direction, and the fourth gate structure is separated from the second gate structure in the X-direction, and
a first gate local connection structure, disposed on the first gate structure and the third gate structure, wherein the first gate local connection structure electrically connects the first gate structure to the third gate structure.

11. The memory device of claim 10, further comprising:
a common source/drain contact, electrically connected to a first source/drain feature shared by the first pass-gate transistor and the first pull-down transistor and a second source/drain feature of the first pull-up transistor; and
a butted contact, electrically connected to the common source/drain feature and a fifth gate structure shared by the second pull-up transistor and the second pull-down transistor.

12. The memory device of claim 10, further comprising:
a first gate end dielectric layer extending along the common boundary,
wherein the first gate end dielectric layer is between the first gate structure and the third gate structure, and separates the first gate structure from the third gate structure.

13. The memory device of claim 12, wherein top surfaces of the first gate structure, the third gate structure, and the first gate end dielectric layer are coplanar with a bottom surface of the first gate local connection structure.

14. The memory device of claim 12, wherein the first SRAM cell further comprises:
a second gate end dielectric layer, extending along a cell boundary that is opposite to the common boundary; and
a second gate local connection structure, disposed on the second gate end dielectric layer and a sixth gate structure of the second pass-gate transistor, wherein the second gate local connection structure partially overlaps the sixth gate structure.

15. The memory device of claim 14,
wherein the first SRAM cell has a cell height in the Y-direction, and
wherein the first gate end dielectric layer and the second gate end dielectric layer continuously extend across the whole cell height.

16. A memory device, comprising:
a first static random access memory (SRAM) cell over a substrate, comprising:
a first pass-gate transistor, comprising first nanostructures that are vertically stacked and wrapped around by a first gate structure;
a first pull-down transistor, comprising second nanostructures that are vertically stacked and wrapped around by a second gate structure; and
a first pull-up transistor, comprising third nanostructures that are vertically stacked and wrapped around by the second gate structure,
wherein the first gate structure and the second gate structure extend in an X-direction and are separated from each other in a Y-direction that is perpendicular to the X-direction,
a second SRAM cell over the substrate and adjacent to the first SRAM cell, comprising:
a second pass-gate transistor, comprising fourth nanostructures that are vertically stacked and wrapped around by a third gate structure;
a second pull-down transistor, comprising fifth nanostructures that are vertically stacked and wrapped around by a fourth gate structure; and
a second pull-up transistor, comprising sixth nanostructures that are vertically stacked and wrapped around by the fourth gate structure,
wherein the third gate structure and the fourth gate structure are aligned with the first gate structure and the second gate structure along the X-direction, respectively,
a first gate end dielectric layer, disposed between the first SRAM cell and the second SRAM cell and extending the Y-direction, wherein the first gate end dielectric layer physically separates the first gate structure from the third gate structure and physically separates the second gate structure from the fourth gate structure; and
a first gate local connection structure, disposed on the first gate structure, the third gate structure, and the first gate end dielectric layer, wherein the first gate local connection structure electrically connects the first gate structure to the third gate structure.

17. The memory device of claim 16, further comprising:
a shallow trench isolation (STI) structure below the first gate structure and the third gate structure,
wherein the first gate end dielectric layer extends into the STI structure by a distance that is in a range from 5 nm to 60 nm.

18. The memory device of claim 16,
wherein the first pass-gate transistor comprises a first source/drain feature and a second source/drain feature disposed on opposite sides of the first gate structure,
wherein the first pull-down transistor comprises the second source/drain feature and a third source/drain feature disposed on opposite sides of the second gate structure, and
wherein the first SRAM cell further comprises bottom isolation layers disposed between the substrate and each of the first source/drain feature, the second source/drain feature, and the third source/drain feature.

19. The memory device of claim 16,
wherein top surfaces of the first gate structure, the third gate structure, and the first gate end dielectric layer are coplanar with a bottom surface of the first gate local connection structure, and
wherein the first gate local connection structure partially overlaps each of the first gate structure and the third gate structure by a range from 3 nm to 20 nm in the X-direction.

20. The memory device of claim 16,
wherein the first gate local connection structure has a length in the X-direction and a width in the Y-direction, and wherein a ratio of the length to the width is in a range from 3 to 10,
wherein the first gate local connection structure has a thickness in a Z-direction that is perpendicular to the X-direction and the Y-direction, and wherein the thickness is in a range from 3 nm to 30 nm.
